(19) United States
(12) Patent Application Publication
(10) Pub. No.: US 2010/0065820 A1
(43) Pub. Date: Mar. 18, 2010

(54) Nanotube Device Having Nanotubes with Multiple Characteristics

(75) Inventor: Thomas W. Tombler, JR., Goleta, CA (US)

Correspondence Address: AKA CHAN LLP, 900 LAFAYETTE STREET, SUITE 710, SANTA CLARA, CA, 95050, US

(73) Assignee: ATOMATE CORPORATION, Santa Barbara, CA (US)

(21) Appl. No.: 11/276,076

(22) Filed: Feb. 13, 2006

Related U.S. Application Data
(63) Continuation-in-part of application No. 11/162,548, filed on Sep. 14, 2005, now Pat. No. 7,345,296.
(60) Provisional application No. 60/653,074, filed on Feb. 14, 2005.

(51) Int. Cl. H01L 29/66; H01L 21/336

(52) U.S. Cl. 257/24; 438/151; 257/E29.168; 257/E21.411; 977/742

(57) ABSTRACT

A carbon nanotube of a nanotube device has at least two segments with different characteristics. The segments meet at a junction and a diameter of the carbon nanotube on either side of the junction is about the same. One segment may be doped differently from another segment. One segment may be p doped and another segment n doped. One segment may be doped with a different carrier concentration from another segment. The nanotube device may be used in power semiconductor devices including power diodes and power transistors. These power devices will be very power efficient, wasting significantly less energy than similar manufactured using silicon technology.

This application claims the benefit of U.S. provisional patent application 60/653,074, filed Feb. 14, 2005 and is a continuation-in-part of U.S. patent application Ser. No. 11/162,548, filed Sep. 14, 2005, which are all incorporated by reference along with other references cited in this application.

### BACKGROUND OF THE INVENTION

The present invention relates to semiconductor devices and their manufacture, and more specifically to carbon nanotube device technology.

The age of information and electronic commerce has been made possible by the development of transistors and electronic circuits, and their miniaturization through integrated circuit technology. Integrated circuits are sometimes referred to as “chips.” Many numbers of semiconductor devices including transistors and diodes are used to build electronic circuits and integrated circuits. Modern microprocessor integrated circuits have over 50 million transistors and will have over 1 billion transistors in the future.

Some type of circuits include digital signal processors (DSPs), amplifiers, dynamic random access memories (DRAMs), static random access memories (SRAMs), erasable programmable read only memories (EPROMs), electrically erasable programmable read only memories (EEPROMs), Flash memories, microprocessors, application specific integrated circuits (ASICs), and programmable logic. Other circuits include amplifiers, operational amplifiers, transceivers, power amplifiers, analog switches and multiplexers, oscillators, clocks, filters, power supply and battery management, thermal management, voltage references, comparators, and sensors.

Electronic circuits have been widely adopted and are used in many products in the areas of computers and other programmed machines, consumer electronics, telecommunications and networking equipment, wireless networking and communications, industrial automation, and medical instruments, just to name a few. Electronic circuits and integrated circuits are the foundation of computers, the Internet, voice over IP (VoIP), and on-line technologies including the World Wide Web (WWW).

There is a continuing demand for electronic products that are easier to use, more accessible to greater numbers of users, provide more features, and generally address the needs of consumers and customers. Integrated circuit technology continues to advance rapidly. With new advances in technology, more of these needs are addressed. Furthermore, new advances may also bring about fundamental changes in technology that profoundly impact and greatly enhance the products of the future.

The building blocks in electronics are electrical and electronic elements. These elements include transistors, diodes, resistors, and capacitors. There are many numbers of these elements on a single integrated circuit. Improvements in these elements and the development of new and improved elements will enhance the performance, functionality, and size of the integrated circuit.

Semiconductor devices are an important building block in electronics. Some examples of semiconductor devices are diodes and transistors. The operation of almost every integrated circuit depends on semiconductor devices and their properties. Semiconductor devices are used in the implementation of many circuits. Improving the characteristics and techniques of making semiconductor devices will lead to major improvements in electronics and integrated circuit.

There is a great demand for increasing performance beyond the boundaries of present-day silicon materials. It is desirable to have semiconductor devices with improved characteristics, especially devices having higher current density, higher thermal conductivity, and higher switching frequency. Therefore, there is a need to provide improved semiconductor device technology.

### SUMMARY OF THE INVENTION

A carbon nanotube of a nanotube device has at least two segments with different characteristics. The segments meet at a junction and a diameter of the carbon nanotube on either side of the junction is about the same. One segment may be doped differently from another segment. One segment may be p doped and another segment n doped. One segment may be doped with a different carrier concentration from another segment. The nanotube device may be used in power semiconductor devices including power diodes and power transistors. These power devices will be very power efficient, wasting significantly less energy than similar manufactured using silicon technology.

The invention will materially contribute to the more efficient utilization and conservation of energy resources. The invention will reduce of energy consumption in numerous devices and systems including automobiles, appliances, and portable electronics. Furthermore, our invention will decrease U.S. dependence on fossil fuels.

The invention is especially suited for creating highly efficient power devices, where a goal is to provide power with the voltage and current to a load with minimum losses, thus greatly improving the efficient utilization of energy resources. The load can be a computer, portable electronics, circuitry in motorized vehicles, industrial equipment, household electronics and appliances, or any other device requiring power.

More specifically, a primary source of wasted energy in power semiconductor devices comes from the on-state resistance of the semiconductor and charging effects. Existing power devices are manufactured using silicon semiconductor technology. By comparison, the invention is based on the material properties of carbon nanotubes and has on-state resistances that are 20 times lower than silicon. This significantly reduces resistive heating in devices and overall energy consumption.

In an embodiment, the present invention relates to transistor and rectifying devices and associated methods making such devices using carbon nanotube technology. Some embodiments of the present invention are particularly applicable to transistors. In an embodiment, the transistors include carbon nanotubes and more specifically, single-walled carbon nanotubes (SWNT). In one implementation, the transistors include single-walled carbon nanotubes within the pores of structures. These structures may use templates that include anodized aluminum oxide or the like. Some embodiments of the present invention are especially suited for power transistor or power amplifier applications, or both. Transistors of the invention may be especially suited for a wide range of frequencies, switches, power supplies, and driving motors. Other embodiments of the invention are particularly applicable to diodes, rectifiers, silicon controlled rectifiers, varistors, thyristors, and related devices. The devices will allow for high currents, high current densities, and high powers, which are particularly suited for power diodes, power rectifiers, and related applications.

In an implementation, the invention is a device including a structure having a first surface and a second surface, where the structure has at least one pore having a first end at the first surface and a second end at the second surface, and the pore extends from the first to the second surface. A carbon nanotube extends from the first end of the pore to the second end. The carbon nanotube has a first segment and a second segment, and the first segment has a different characteristic from the second segment.

In an implementation, the invention is a device including a structure having a first surface and a second surface, where the structure has pores, each having a first end at the first surface and a second end at the second surface, and each pore extending from the first to the second surface. A number a carbon nanotubes extends from the first end of the pores to the second end of the pores. Each carbon nanotube has n junctions and n+1 segments, where n is an integer, and at least two segment of each carbon nanotube has different characteristics.

In an implementation, the invention is a device including a structure having a first surface and a second surface, where the structure has pores, each having a first end at the first surface and a second end at the second surface, and each pore extending from the first to the second surface. A number of carbon nanotubes extends from the first end of the pores to the second end of the pores. Each carbon nanotube has a characteristic which varies along a length of the carbon nanotube.

In an implementation, the invention is a method of making a device including anodizing an aluminum substrate to produce an alumina template with a plurality of pores, each having a pore diameter. The alumina template having pores is exposed to a hydrocarbon gas at a temperature to grow carbon nanotubes in the pores, each carbon nanotube having an outer diameter less than the pore diameter in the template in which said carbon nanotube is produced. A first segment of each carbon nanotube is doped differently from a second segment of each carbon nanotube. A first electrode region is formed to electrically connect to first ends of the carbon nanotubes. A second electrode region is formed to electrically connect to second ends of the carbon nanotubes.

In an implementation, the invention is a method of making a device including providing a porous structure; processing to obtain nanotubes in pores of the porous structure; and processing first segments of the nanotubes to have a first characteristic different from a second characteristic of second segments of the nanotubes.

In an implementation, the invention is a device including an insulator structure that defines pores; carbon nanotubes within at least some of the pores; and at least one junction in multiple ones of the carbon nanotubes, where the junction defines a first region and a second region having of different properties. A first electrode on a first side of the structure connects to multiple ones of the carbon nanotubes. A second electrode on a second side of the structure connects to multiple ones of the carbon nanotubes. A diameter of a first region of a carbon nanotube is about equal to a diameter of a second region of the carbon nanotube.

Other objects, features, and advantages of the present invention will become apparent upon consideration of the following detailed description and the accompanying drawings, in which like reference designations represent like features throughout the figures.

### BRIEF DESCRIPTION OF THE DRAWINGS

FIG. 1 shows a computing system incorporating the invention.

FIG. 2 shows a motor vehicle system incorporating the invention.

FIG. 3 shows a telecommunications system incorporating the invention.

FIG. 4 shows a block diagram of a system incorporating the invention.

FIG. 5 shows a circuit symbol for a carbon nanotube transistor device.

FIG. 6 shows a DC-to-AC inverter circuit using carbon nanotube devices.

FIG. 7 shows a DC-DC converter circuit using carbon nanotube devices.

FIG. 8 shows a top view of a porous structure used in a technique of fabricating carbon nanotube devices of the invention.

FIG. 9 shows a cross-sectional view of a porous structure used in a technique of fabricating carbon nanotube devices of the invention.

FIG. 10 shows a cross-sectional view a porous structure supported by a structure or substrate without pores.

FIG. 11 shows a structure with carbon nanotubes in the pores of the insulating structure and top and bottom electrodes.

FIG. 12 shows a structure where a substrate is used and connected to a bottom electrode.

FIG. 13 shows a structure with carbon nanotubes having p-doped segments and n-doped segments.

FIG. 14 shows a structure with carbon nanotubes having lightly p-doped segments and more heavily p-doped segments.

FIG. 15 shows a structure with the pores filled with a material.

FIG. 16 shows a structure with the pores filled with multiple materials.

FIG. 17 shows a carbon nanotube transistor structure.

FIG. 18 shows a structure which has a first insulating layer with pores and a second material with pores.

FIG. 19 shows a structure where a first insulating layer is removed after pore transfer and the second material with pores remains.

FIG. 20 shows a flow diagram of using a porous structure for fabricating devices of the invention by synthesizing carbon nanotubes in the pores.

FIG. 21 shows a flow diagram of using a substrate and a porous structure for fabricating devices of the invention by synthesizing carbon nanotubes in the pores.

FIG. 22 shows a flow diagram for fabricating devices of the invention by transferring carbon nanotubes to the pores.

### DETAILED DESCRIPTION

The invention provides a carbon nanotube device and techniques for manufacturing such a device. The device includes nanotubes having multiple properties or characteristics. The nanotubes may be single-walled or multiwalled carbon nanotubes. For example, a carbon nanotube device may be made of multiple nanotubes, each nanotube having two or more segments, where segments have different properties or characteristics from adjacent segments. For example, one segment may be an n-type semiconductor material and another segment may be a p-type semiconductor material. There is a junction where two segments meet. This carbon nanotube device may be part of a diode or other semiconducting device. The device may be a power or high-power device, capable of passing relatively high currents compared to standard devices.

In a specific embodiment, the carbon nanotube technology of the invention is incorporated in a carbon nanotube transistor. The carbon nanotube transistor may be a single-walled carbon nanotube (SWNT) transistor, where the single-walled carbon nanotube is a channel of the transistor. A specific application of the SWNT transistor of the invention is as a power transistor, a type of transistor capable of passing relatively high currents compared to standard transistors. Further, the invention provides diode, silicon-controlled rectifier, and other related devices having carbon nanotubes, and methods for making such devices. These may be manufactured independently or in combination with any device of the invention.

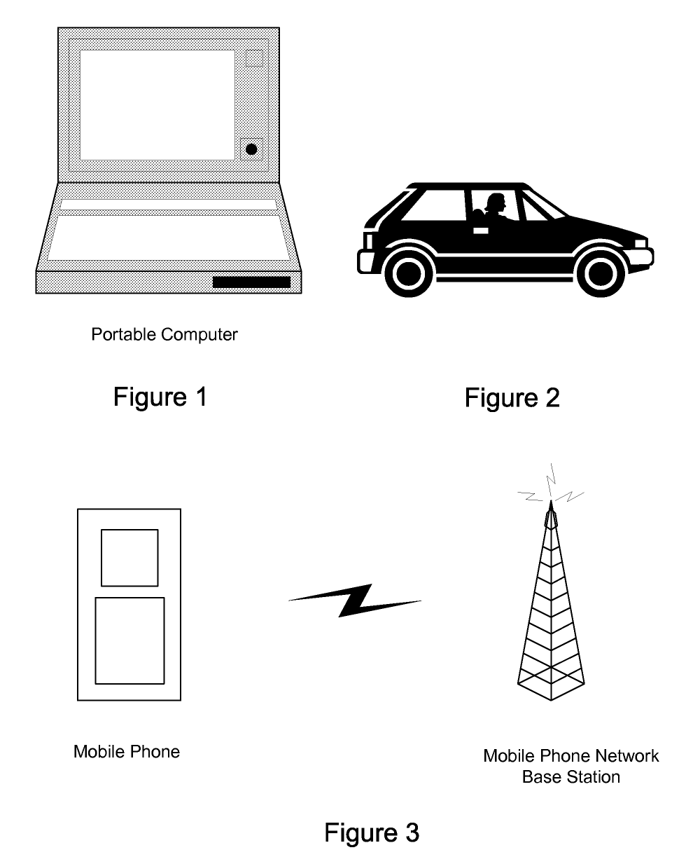

FIG. 1 shows an example of an electronic system incorporating one or more carbon nanotube transistors or rectifying devices of the invention, or combinations of these. Electronic systems come in many different configurations and sizes. Some electronic systems are portable or handheld. Such portable systems typically may be battery operated.

The battery is typically a rechargeable type, such as having nickel cadmium (NiCd), nickel metal hydride (NiMH), lithium ion (Li-Ion), lithium polymer, lead acid, or another rechargeable battery chemistry. The system can operate for a certain amount of time on a single battery charge. After the battery is drained, it may be recharged and then used again.

In a specific embodiment, the electronic system is a portable computing system or computer, such as a laptop or notebook computer. A typical computing system includes a screen, enclosure, and keyboard. There may be a pointing device, touchpad, or mouse equivalent device having one or more buttons. The enclosure houses familiar computer components, some of which are not shown, such as a processor, memory, mass storage devices, battery, wireless transceiver, and the like. Mass storage devices may include mass disk drives, floppy disks, magnetic disks, fixed disks, hard disks, CD-ROM and CD-RW drives, DVD-ROM and DVD-RW drive, Flash and other nonvolatile solid-state storage drives, tape storage, reader, and other similar devices, and combinations of these.

Other examples of portable electronics and battery-operated systems include electronic game machines (e.g., Sony PlayStation Portable), DVD players, personal digital assistants (PDAs), remote controls, mobile phones, remote controlled robots and toys, power tools, still and movie cameras, medical devices, radios and wireless transceivers, and many others. The transistor of the invention may be used in any of these and other electronic and battery-operated systems to provide similar benefits.

Transistors or rectifying devices of the invention, or combinations of these, may be used in various circuits of electronic systems including circuitry for the rapid recharging of the battery cells and voltage conversion, including DC-DC conversion. For example, each laptop power supply typically has eight power transistors. Transistors of the invention may be used in circuitry for driving the screen of the system. The screen may be a flat panel display such as a liquid crystal display (LCD), plasma display, or organic light emitting diode (OLED) display. Transistors of the invention may be used in circuitry for the wireless operation of the system such as circuitry for wireless networking (e.g., Wi-Fi, 802.11a, 802.11b, 802.11g, or 802.11n) or other wireless connectivity (e.g., Bluetooth).

FIG. 2 shows an example of a vehicle incorporating one or more carbon nanotube transistors or rectifying devices of the invention, or combinations of these. Although the figure shows a car example, the vehicle may be a car, automobile, truck, bus, motorized bicycle, scooter, golf cart, train, plane, boat, ship, submarine, wheelchairs, personal transportations devices (e.g., Segway Human Transporter (HT)), or other. In a specific embodiment, the vehicle is an electric vehicle or hybrid-electric vehicle, whose motion or operation is provided, at least in part, by electric motors.

In an electric vehicle, rechargeable batteries, typically lead acid, drive the electric motors. These electric or hybrid-electric vehicles include transistors or devices of the invention in, among other places, the recharging circuitry used to recharge the batteries. For a hybrid-electric vehicle, the battery is recharged by the motion of the vehicle. For a fully electric vehicle, the battery is charged via an external source, such as an AC line or another connection to a power grid or electrical power generator source. The vehicular systems may also include circuitry with transistors of the invention to operate their on-board electronics and electrical systems.

FIG. 3 shows an example of a telecommunications system incorporating one or more carbon nanotube transistors or rectifying devices of the invention, or combinations of these. The telecommunications system has one or more mobile phones and one or more mobile phone network base stations. As described above for portable electronic devices, each mobile phone typically has a rechargeable battery that may be charged using circuitry with transistors or devices of the invention. Furthermore, for the mobile phone or other wireless device, there may be transceiver or wireless broadcasting circuitry implemented using transistors of the invention. And a mobile phone network base station may have transceiver or broadcasting circuitry with transistors or devices of the invention.

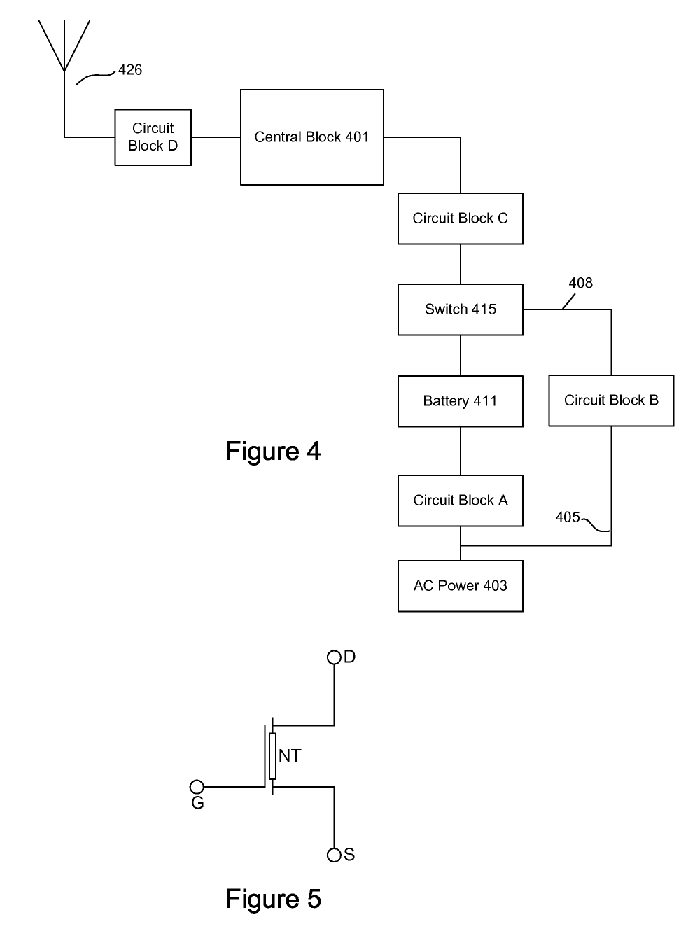

FIG. 4 shows a more detailed block diagram of a representative system incorporating the invention. This is an exemplary system representative of an electronic device, notebook computer, vehicle, telecommunications network, or other system incorporating the invention as discussed above. The system has a central block 401, a component of the system receiving power. The central block may be a central processing unit, microprocessor, memory, amplifier, electric motor, display, or other.

DC power is supplied to the central block from a rechargeable battery 411. This battery is charged from an AC power source 403 using a circuit block A including carbon nanotube transistors or devices of the invention. Circuit block A may include circuitry to convert AC power to DC power, and this circuitry may also include carbon nanotube transistors or rectifying or other devices. Although a single circuit block A is shown to simplify the diagram, the circuitry may be divided into two circuit blocks, one block for AC-to-DC conversion and another block for the recharging circuitry.

Central block may be a device that can be powered either by the AC line or from the battery. In such an embodiment, there would be a path from AC power, connection 405, circuit block B, and connection 408 to a switch 415. The battery is also connected to switch 415. The switch selects whether power is supplied to the central block from the battery or from the AC power line (via circuit block B). Circuit block B may include AC-to-DC conversion circuitry implemented using carbon nanotube transistors or devices of the invention. Furthermore, in an implementation of the invention, switch 415 includes carbon nanotube transistors or devices of the invention.

Circuit block B may be incorporated into a power supply for central block. This power supply may be switching or linear power supply. With carbon nanotube transistors of the invention, the power supply will be able to provide more power in a more compact form factor than using typical transistors. The power supply of the invention would also generate less heat, so there is less likelihood of overheating or fire. Also, a fan for the power supply may not be necessary, so a system incorporating a power supply having nanotube transistors of the invention will be quieter.

The path from AC power through circuit block B is optional. This path is not needed in the case there is not an option to supply power from an AC line to the central block. In such a case, switch 415 would also not be used, and battery 411 would directly connect to circuit block C. As can be appreciated, there are many variations to how the circuitry of the system in the figure may be interconnected, and these variations would not depart from the scope of the invention.

Circuit block C is circuitry such as a DC-to-DC power converter or voltage regulator including carbon nanotube transistors or devices of the invention. This circuitry takes DC power of a certain voltage and converts it to DC voltage at a different voltage level. For example, the battery or output of circuit block B may have an output voltage of about 7.2 volts, but the central block uses 3 volts. Circuit block C converts the 7.2 volts to 3 volts. This would be a step-down converter since voltage of a higher level is being converted to a lower level.

In the case central block 401 has a wireless component, a path including circuit block D and antenna 426 will be used to transmit and receive wireless signals. Circuit block includes carbon nanotube transistors of the invention to perform the signal transmission or reception. For example, the carbon nanotube transistors may be used as output devices in an amplifier generating the wireless signal. In an implementation of the invention without a wireless component, then circuit block D and the antenna would not be present.

FIG. 5 shows a symbol of a carbon nanotube transistor of the invention. According to the invention, transistors are manufactured using carbon nanotubes (CNTs). And more specifically, field-effect transistors (FETs) are manufactured using single-walled carbon nanotubes. The transistor has a gate node G, drain node D, and source node S. This carbon nanotube transistor of the invention does not have a bulk, substrate, or well node as would a typical MOS transistor of an integrated circuit. In other embodiments of the invention, the carbon nanotube transistor may have a bulk node.

When an appropriate voltage is applied to the gate node, a channel can form in a carbon nanotube, denoted by NT. Current can flow from drain to source. Operation of the single-walled carbon nanotube transistor of the invention is analogous to a metal oxide semiconductor (MOS) transistor.

The single-walled carbon nanotube is a relatively recently discovered material. A single-walled carbon nanotube can be conceptually described as a single sheet of graphite (also called graphene) that is configured into a seamless cylindrical roll with diameters typically about 1 nanometer, but can range from about 0.4 to about 5 nanometers. The cylinder may be a one-layer thick layer. For example, a nanotube may be 0.5, 0.7, 0.8, 0.9, 1.0, 1.1, 1.2, 1.3, 1.6, 2, 2.5, 2.7, 3, 3.2, 3.6, 3.8, 4.0, 4.2, 4.3, 4.5, 4.6, 4.7, or 4.9 nanometers. Depending on the process technology, single-walled carbon nanotubes may have diameters less than 0.7 nanometers or greater than 5 nanometers.

In addition to single-walled carbon nanotubes, another type of carbon nanotube is a multiwalled carbon nanotube (MWNT). A multiwalled carbon nanotube is different from single-walled carbon nanotube. Instead of a single carbon nanotube cylinder, multiwalled carbon nanotubes have concentric cylinders of carbon nanotubes. Consequently, multiwalled carbon nanotubes are thicker, typically having diameters of about 5 nanometers and greater. For example, multiwalled carbon nanotubes may have diameters of 6, 7, 8, 10, 11, 15, 20, 30, 32, 36, 50, 56, 62, 74, 78, 86, 90, 96, or 100 nanometers, or even larger diameters.

Single-walled carbon nanotubes have unique electrical, thermal, and mechanical properties. Electronically they can be metallic or semiconducting based on their chirality or helicity, which is determined by their (n, m) designation, which can be thought of as how the graphite sheet is rolled into a cylinder. Typically, individual single-walled carbon nanotubes can handle currents of 20 microamps and greater without damage. Compared to multiwalled carbon nanotubes, single-walled carbon nanotubes generally do not have structural defects, which is significant for electronics applications.

Single-walled carbon nanotube material has proven to have incredible materials properties. It is the strongest known material—about 150 times stronger than steel. It has the highest known thermal conductivity (about 6000 W/m·K). The properties of semiconducting single-walled carbon nanotubes are indeed promising. They may be used in field-effect transistors (FETs), nonvolatile memory, logic circuits, and other applications.

With regard to transistor applications, single-walled nanotube devices have “on” resistances and switching resistances that are significantly lower than those of silicon. Transistors based on single-walled carbon nanotube technology can handle considerably higher current loads without getting as hot as conventional silicon devices. This key advantage is based on two factors. First, the lower “on” resistance and more efficient switching results in much lower heat generation. Second, single-walled carbon nanotubes have high thermal conductivity ensures that the heat does not build up.

Important considerations in carbon nanotube field effect transistor (CNTFET) design and fabrication are threefold. A first consideration is the controlled and reproducible growth of high quality single-walled carbon nanotubes with the desirable diameter, length, and chirality. A second consideration is the efficient integration of nanotubes into electronic structures. And a third consideration is current nanotube growth and device fabrication processes need to be improved significantly so that they are amenable to scalable and economical manufacturing.

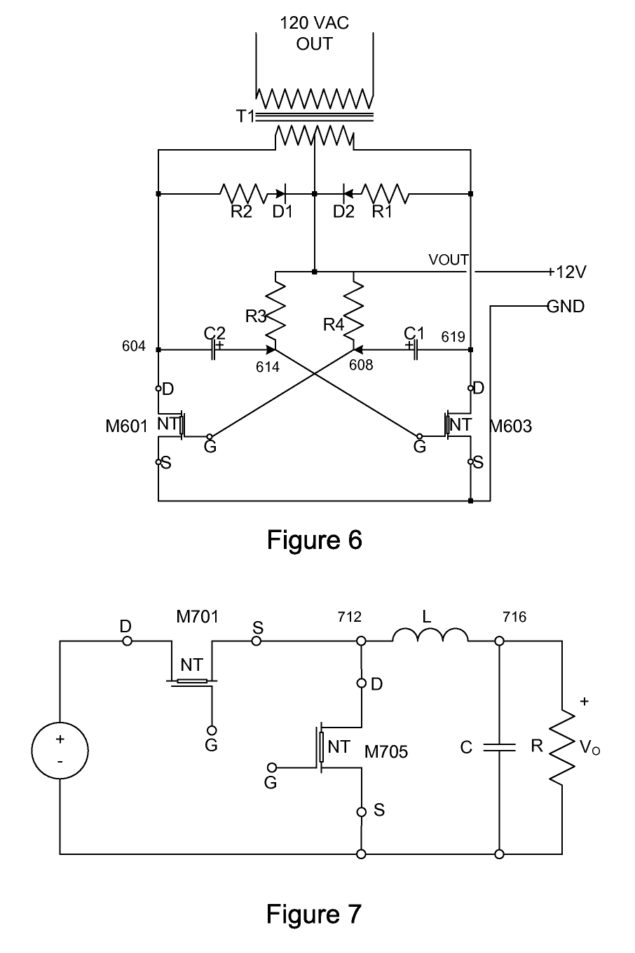

FIG. 6 shows an AC-to-DC converter circuit using two carbon nanotube transistors, M601 and M603, of the invention. The circuitry takes an AC voltage input, such as 120 volts provided at transformer T1 and provides a DC voltage output, such as the 12 volts indicated in the figure. The converter may be designed to take as input any AC voltage, but 120 volts was selected since this is the standard AC line voltage in the U.S. The circuitry may be designed to output any desired DC voltage, less than or more than 12 volts, such as 2 volts, 3, volts, 5 volts, 6 volts, 16 volts, 18 volts, or 20 volts, by varying the circuit components. For example, the resistances R1, R2, R3, and R4 may be varied.

Single-walled carbon nanotube transistor M601 is connected between a node 604 and ground. A gate node of M601 is connected to node 608. A capacitor C2 is connected between 604 and 614, which is connected to a gate of single-walled carbon nanotube transistor M603. M603 is connected between node 619 and ground. A capacitor C1 is connected between 608 and 619. Resistor R3 is connected between DC output, VOUT, and 614. Resistor R4 is connected between VOUT and 608. Between VOUT and 604 are a diode D1 and resistor R2. Between VOUT and 619 are a diode D2 and resistor R1. Nodes 604 and 619 are connected to windings of transformer T1.

The AC-to-DC converter may output significant currents because the converter provides power for circuits having relatively large power needs. Therefore, in such cases, carbon nanotube transistors M601 and M603 will pass relatively large currents. In addition, in a battery recharging battery application, by increasing the current M601 and M603 can pass without overheating or damaging the devices, this will speed-up the rate at which batteries may be recharged.

FIG. 7 shows a DC-to-DC converter circuit using two carbon nanotube transistors, M701 and M705, of the invention. The circuit takes a DC input voltage, VIN, and outputs a different DC voltage, VO. For example, VIN may be 7.2 volts or 12 volts, and VO may be 5 volts or 3 volts. Voltage conversion is used in many applications such as portable electronics because batteries may not provide output at a desired voltage level or at a voltage compatible with electronics.

This circuit may also be part of a DC inverter circuit, in which case a voltage output of opposite polarity to the input voltage is provided. For example, if the input voltage is positive, the output voltage of the inverter would be negative. Or if the input voltage is negative, the output voltage of the inverter would be positive.

Single-walled carbon nanotube transistor M701 is connected between VIN+ and node 712. Single-walled carbon nanotube transistor M705 is connected between node 712 and VIN− (or ground). An inductor L is connected between 712 and 716. A capacitor and resistor are connected between 716 and VIN−. An output VO is taken between node 716 and ground.

In a further embodiment of the invention, there may be a first diode connected between a drain and source of transistor M701, and a second diode connected between a drain and source of transistor M705. The first diode may be connected so that current will be allowed to flow in a direction from node 712 to VIN+. The second diode may be connected so that current will be allowed to flow in a direction from ground to node 712.

These diodes may be designed or fabricated using any technique used to obtain devices with diode characteristics including using a diode-connected transistor, where a gate and drain of the transistor are connected together, or other transistor techniques. In another embodiment, a diode may be integrated with a nanotube transistor using a carbon nanotube with a junction as will be discussed in more below.

In operation, the converter circuit converts the VIN voltage to a VO or VOUT voltage. A first signal is connected to a gate of transistor M701, and a second signal is connected to a gate of transistor M705. The first and second signals may clock signals or oscillator signals including square waves, pulse trains, sawtooth signals, and the like. The first and second signals and may be generated by a controller for the converter circuit.

Power transistors and devices are high power output stages in electronics that typically carry high currents and power. They are elements in power amplifiers and are used to deliver required amounts of current and power efficiently to a load. Applications include power delivery to devices within integrated circuits, personal computers, cellular phones, wireless base stations, and a variety of electrical devices. Power transistors and devices are also used for high current switches and supplying power to motors.

At the present time, power transistors are bipolar junction transistors (BJT) or metal oxide semiconductor field-effect transistors (MOSFET) based on silicon technology. In addition to these silicon-based devices, other materials are used such as gallium arsenide and gallium nitride. However, silicon bipolar junction transistors and silicon metal oxide semiconductor field-effect transistors, specifically laterally diffused metal oxide semiconductor, dominate the field. The entire power transistor device contains a multitude of linked individual transistors in order to distribute the total current and power. Relevant parameters in power transistors include current carrying and power capability, current gain, efficiency, and thermal resistance.

There are a number of challenges to commercialization of carbon nanotube devices and replacing current semiconductor technologies, including chirality control, location and orientation control, size and length control, and overall quality control of the properties of single-walled or multiwalled carbon nanotubes on a large scale. These are addressed by the present invention.

An embodiment of the invention is a carbon-nanotube-based power device, including a number of carbon nanotubes with multiple electrical properties. This structure may include aluminum oxide or other material. An electrically conductive source and drain connect each side of vertically aligned carbon nanotubes. In an embodiment, the carbon nanotubes are single-walled carbon nanotubes. In another embodiment, the carbon nanotubes are multiwalled carbon nanotubes. In another embodiment, the carbon nanotubes are a combination of single and multiwalled carbon nanotubes. The carbon nanotubes are within the pores.

A gate electrode is optional. In some embodiments of the invention, there is a gate electrode is patterned to modulate the carbon nanotube electrical conduction effectively and is electrically isolated from the source and drain. In other embodiments of the invention, there is no gate electrode. Furthermore, in a device, there may be multiple gate electrode elements which are connected together to form one large gate. For multiple gate electrodes may be electrically connected in parallel to form a larger gate. The size of this larger gate will be the sum or approximately the sum of the sizes of the smaller gate.

In other embodiments of the invention with a gate, the gate may be a split gate, where two or more gate electrode is connected to two or more sources or inputs. There may be any number of gates in a split gate design, two, three, four, five, six, seven, eight, nine, ten, eleven, twelve, thirteen, fourteen, fifteen, or sixteen or more. As an example, a first gate electrode may be connected to an input A, and a second gate electrode may be connected to an input B. Inputs A an B may be independent of each other such as when they are connected to independent sources. This means that A can be varied independently of A and B may be varied independently of B. Inputs A an B may be dependent of each other such as when the are connected to dependent sources. This means when A is varied, B will vary in some relationship to A. Alternatively, input A may depend on B.

The device of the invention obtains higher current densities and total power densities than can devices according to conventional technology, and the device enables higher current and power devices or equivalent current and power in smaller sized devices.

In one embodiment of the invention, carbon nanotubes are synthesized within pores of a porous structure. The porous structure is fabricated through any competent method using any competent material. For example, anodization techniques are used on aluminum to produce aluminum oxide. Suitable and effective catalyst for carbon nanotube synthesis is deposited at the bottom of the pore.

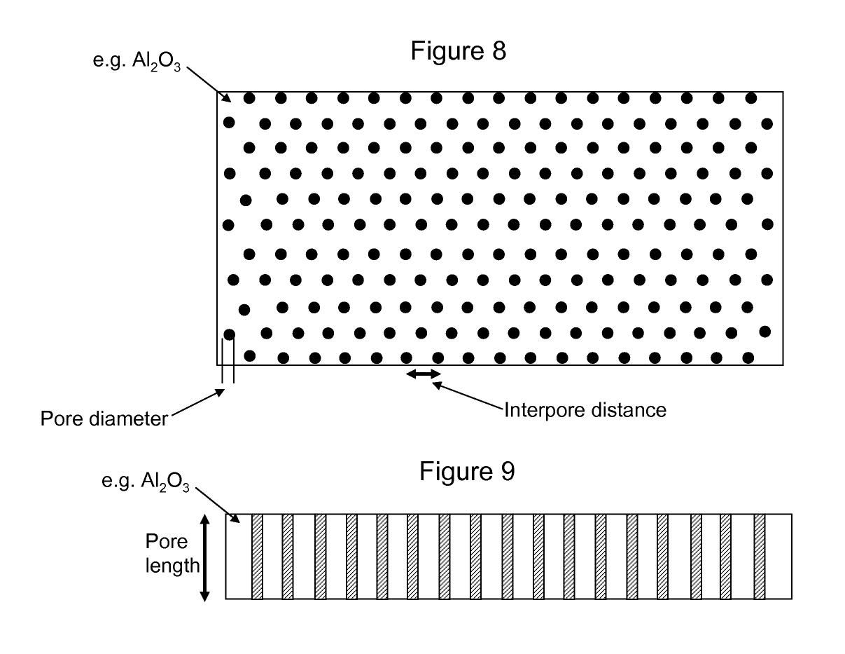

To fabricate a device of the invention, a porous structure or substrate is used. FIG. 8 shows a top view of such a porous structure or substrate. FIG. 9 shows a cross-sectional view of the porous structure. The porous structure may be, for example, an aluminum oxide, Al₂O₃, structure in form of an aluminum oxide membrane that achieves a given pore density and pore size. There are many numbers of pores and each pore is an opening in the structure. In a porous structure, not necessarily every pore is completely open from one side to the opposite side of the structure. For example, some percentage of the pores may be open only partially through. These pores are incomplete pores and may not be used since a nanotube in such a pore is not accessible from both sides of the structure.

In an embodiment, this opening is generally circular in shape and has a diameter. A pore has pore walls and is generally a cylindrical opening. The pore opening may be other shapes and is not necessarily what would be considered a perfect cylindrical (or other shaped) opening. The porous structure may be made from other materials other than aluminum oxide including silicon, silicon germanium, titanium oxide, niobium oxide, tantalum oxide, zirconium oxide, gallium nitride, germanium, gallium arsenide, plastic, polymer, glass, or quartz, or the like, or combinations of these.

The pores will have a pore diameter, an interpore distance, and a pore length. Pore diameter will be about 10 nanometers to 200 nanometers. Pore density will typically be about 10⁸ per square centimeter to about 10¹¹ per square centimeter. Below is a table A of density of the pores and corresponding interpore distance for various embodiments of the invention for a hexagonal arrangement of pores.

TABLE A

| Density of | |
|---|---|
| Pores (per | Interpore |
| square | Distance |
| centimeter) | (nanometers) |
| 2 * 10¹¹ | 24 |
| 1 * 10¹¹ | 34 |
| 5 * 10¹⁰ | 48 |
| 2 * 10¹⁰ | 76 |
| 1 * 10¹⁰ | 107 |
| 1 * 10⁹ | 340 |

Pore length will typically be from about 500 nanometers to about 1.5 microns. However, in other embodiments, the pore length may be less than 500 nanometers such as short as 50 nanometers or less, or the pore length may be longer than 1.5 microns, such as up to 4 microns or more.

A factor in determining the interpore distance will be the integrity of the supporting structure. When there is another support structure which the porous structure is on, the thickness will likely be thinner (i.e., pore length will be shorter). For example, the porous aluminum oxide structure may be on a sapphire, diamond, or silicon sheet that provides structural integrity. For an aluminum oxide structure only (i.e., no additional supporting structure), a thickness from about 25 microns to about 100 microns should provide sufficient support.

When a support structure is used, a conductive material such as metal such as gold, titanium, palladium, platinum, or other metal may be deposited at a junction of the support structure the pores. This conductive material will be helpful in attaching or contacting a carbon nanotube to the support structure, especially when the support structure is an insulator or semiconductor or if the electrical contact is insufficient. Only a relatively small amount of conductive material may be needed to aid in nanotube adhesion or electrical contact, or both. The conductive material will not necessarily form a rectifying junction.

FIG. 8 shows pores arranged in a hexagonal pattern. FIG. 9 shows a cross-sectional view of the pores. Each pore is at a vertex of a hexagon, and there is also one pore in the center of the hexagon. This pattern is repeated throughout the porous structure. Any other competent pattern may also or instead be used. For example, the pores may be arranged in a triangular, square, rectangular, pentagonal, octagonal, trapezoidal, or regular structure. In other embodiments of the invention, the pores may be distributed in a random arrangement. There may be two or more different arrangements of pores in the same porous structure. For example, one portion of the structure has a hexagonal pattern and another portion has an octagonal structure. This may be useful in providing two or more carbon nanotube devices on the same structure with different characteristics.

Further, there may be different arrangements of the same pattern in the same porous structure. For example, there may be two hexagonal patterns on the same porous structure, but the hexagonal patterns may have some offset from each other. One hexagonal pattern may be shifted some linear distance from the other. Or one hexagonal pattern may be rotated at an angle compared to the other hexagonal pattern.

For a hexagonal pattern, a pitch is calculated by taking the square root of (1/(sine 60*density of pores)). The pitch is the distance between two pores and is therefore a way to estimate the pore diameter, which should be less than the pitch since the structure will have a certain wall thickness for sufficient structural integrity. In an embodiment, a pore diameter will range from about 20 nanometers to about 35 nanometers. In another embodiment, the pore diameter will range from about 15 nanometers to about 50 nanometers. In another embodiment, the pore diameter will range from about 5 nanometers to about 250 nanometers.

The structure may be made by any competent method such as electrochemical anodized etching of aluminum. The length and density of the pores is determined by anodization conditions including voltage and time. Pores can be widened after fabrication by chemical techniques such as phosphoric acid etching at a variety of temperatures such as, for example, room temp, 60 degrees Celsius, and other temperatures. Other chemical techniques include using chromic acid or a combination of chromic and phosphoric acid.

The pattern of pores in the structure may be made by transfer from a porous structure that is primarily made of aluminum oxide and that has been made porous as discussed below. The transfer of pore patterns can be by any competent method such as by using the porous aluminum oxide structure as a mask and etching through the pores into the other medium such as into the silicon, silicon germanium, and so forth. As will be discussed in more detail below, the carbon nanotubes are then synthesized directly within or are transferred to the pores of the new medium. Source, drain, and optional gate electrodes are defined to form a carbon nanotube device of the invention.

In an embodiment, aluminum is the starting substrate material. And this aluminum precursor may be 99.99 percent pure or better. The more pure the aluminum precursor is the better the results generally will be in terms of device yield and device characteristics.

Before pore fabrication, the precursor is cleaned and annealed. Typically the aluminum is electropolished for some time. Then the substrate is anodized or oxidized to form aluminum oxide where a first layer of pores is created. This first layer of pores does not have to be too organized and consistent; this layer may be removed by chemical means. Then the substrate may be anodized or oxidized again. This second stage of pore fabrication is then used to make a regular arrangement of quality pores. Even more anodization steps may be performed to further improve ordering.

In an embodiment of the invention, when the aluminum is formed on a substrate, electropolishing may not be needed and instead, cleaning will be used, or cleaning and annealing will be used. Electropolishing may remove too much aluminum, and so it may not work well with evaporated or sputtered films of aluminum. These techniques form a relatively thin film of aluminum. With such a thin film, typically there is not sufficient control during the electropolishing process to ensure not too much aluminum is removed. However in the case of bulk aluminum or aluminum foil, then the process may include annealing and electropolishing during anodization. A second anodization, after the first, is optional. Decent pore formation may occur without the second anodization. However, the second anodization is useful in order to avoid steps such as electropolishing.

This process makes pores with one side exposed and a thin barrier layer of aluminum oxide film on the remaining aluminum bulk or substrate on the other end of the pore. In some embodiments, some processes may have no barrier layer when a substrate is used instead of bulk aluminum. The aluminum bulk can be etched or removed by a chemical means to open the other side of the pores. This will leave the aluminum oxide film with a thickness defined by the etching conditions (i.e., time). It is usually about a micron to tens of microns in thickness.

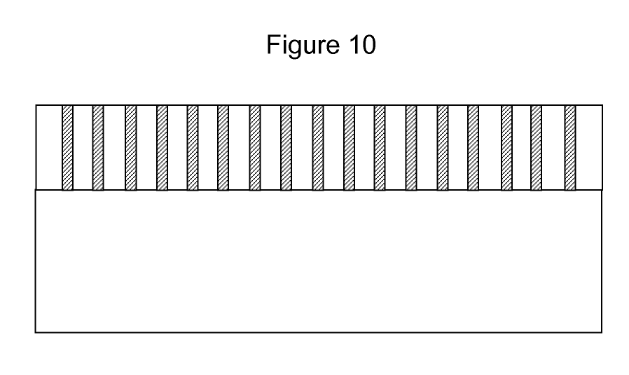

FIG. 10 illustrates the structure with the number of pores on a substrate. A significant number of the pores can extend all the way to the substrate. The substrate can be any material including conductor, semiconductor, insulator, plastic, or other. The substrate can be the same bulk material of the porous structure. The substrate can be used for supporting the structure with the number of pores, which is particularly useful when the structure is less than about 10 microns thick. The substrate further enhances the structural rigidity of the porous structure, since thinner porous structures are generally more fragile and difficult to process.

The structure in FIG. 10 may be the result in intermediate step in the processing of a device according to the invention. For example, the substrate material may be removed in a subsequent processing step, leaving only the porous structure.

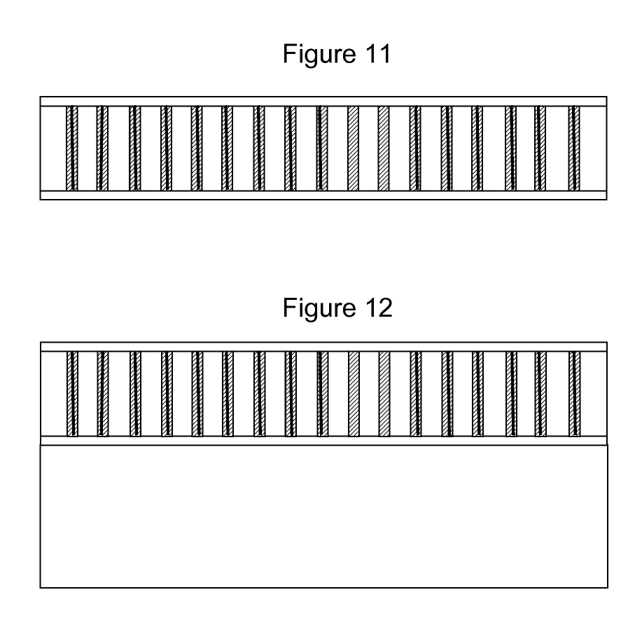

FIG. 11 shows a cross-sectional view of a device with carbon nanotubes in the pores of the porous structure and top and bottom electrodes defined. The porous structure may be an insulating material. During the processing, some percentage of the pores may not have a carbon nanotube, and this is reflected in the figure.

Carbon nanotubes can be synthesized within the pores or transferred to the pores. It is desirable to provide one carbon nanotube per pore, where the carbon nanotube has an effective junction and has both ends exposed at or outside the pore in order to make metal connections. The carbon nanotube's length should be at least equal to the pore length.

Due to redundancy and a large number of pores per unit area, to have an effective nanotube device of the invention, not all pores need to yield an effective carbon nanotube device component. Some amounts of missing or defective pores; missing, noneffective, or incomplete carbon nanotubes; carbon nanotube removed by device architecture requirements; or other yield issues will not make the device inoperative. The fact that not all pores yield an effective carbon nanotube device will not render the device defective or inoperative, in view of redundancy and device density.

Some nanotubes may have undesirable characteristics. For example, some nanotubes may be metallic single-walled carbon nanotubes or semiconducting single-walled carbon nanotubes that do not deplete effectively with the electric gating (when the device being fabricated includes a gate). These undesirable carbon nanotube devices can be removed by any competent technique such as chemical, mechanical, or electrical techniques, and the like, or combinations of these techniques. One specific technique is to use acids such as nitric acid to etch metallic tubes at a faster rate than semiconductors. Another technique is electrical burn-off with protection where the gate is used to turn off the “wanted” semiconducting tubes and then flow a sufficient current through the metallic tubes until they fail. The current to cause failure or electrical breakdown of the undesirable carbon nanotubes may be over above about 15 microamps to about 25 microamps per tube, or even higher currents may be used. Due to the redundancy and device density, even in the case when not all pores yield an effective carbon nanotube device, this will not render the device defective or inoperative.

In some embodiments of the invention, high current densities are obtained. For example, some embodiments of the present invention can be configured by including sufficient density of functional carbon nanotubes to obtain current density of greater than about 1000 amperes per square centimeter. Depending on the density and current contribution of each carbon nanotube, the current density may be greater than 1000 amperes per square centimeter, such as 2000 amperes per square centimeter, 3000 amperes per square centimeter, 4000 amperes per square centimeter, or 5000 or more amperes per square centimeter. The current density may be less than 1000 amperes per square centimeter. The current density may be much higher than 5000 amperes per square centimeter, such as 10¹¹ amperes per square centimeter.

Direct synthesis of carbon nanotubes within the pores can use any competent method. In one embodiment of the present invention, catalyzed chemical vapor deposition is used. Fabricate pores in the structure with an appropriate catalyst for carbon nanotubes at the bottom of the pores. The appropriate catalyst may be, for example, iron, nickel, cobalt, molybdenum, or combinations of these, or combination with other metals, where the catalyst may be placed through metal deposition such as by metal evaporators or electrochemical deposition of metals or by a wet deposition of catalyst where the metal catalyst nanoparticle or particles is supported by a larger inorganic support or an organic shell (such as a ferritin protein or dendrimer). In another embodiment, chemical vapor deposition is used without the presence of a catalyst.

In an embodiment of the invention, a technique includes performing chemical vapor deposition (CVD) at 400 degrees to 1200 degrees Celsius to synthesize carbon nanotube devices within the pores. The results may be that about 95 percent or higher of the carbon nanotubes are semiconducting. In another embodiment, 70 percent or higher of the carbon nanotubes are semiconducting. However, lower percentages such as at least 60 percent or lower can also be tolerated to obtain a working device.

In another embodiment of the present invention, a method is as follows. Fabricate pores in the in the form of aluminum oxide film on the aluminum bulk. In an embodiment, the pores and aluminum oxide are formed at the same time as the aluminum is being oxidized. Place an appropriate catalyst at the bottom of the pores to form carbon nanotubes. The appropriate catalyst may be, for example, iron, nickel, or cobalt, or any combination of these metals, or any combination of one or more of these with other metals. Typically the catalyst is in the form of nanoparticles that is the appropriate size, usually 1 nanometer to 4 nanometers in diameter. In other implementations, the catalyst may be larger than 4 nanometers. These nanoparticles may be obtained through metal deposition such as by metal evaporators, electrochemical deposition of metals, or a wet deposition of catalyst where the metal catalyst nanoparticle or particles is supported by a larger inorganic support or an organic shell, such as a ferritin protein.

The catalyst particle should stay the appropriate size for synthesis of the desired carbon nanotubes (e.g., single or multiwalled). Synthesis can occur with the aluminum bulk still on the bottom of the structure if temperatures are less than about 600 degrees Celsius to about 650 degrees Celsius. The template with aluminum oxide only can go to higher temperature, for example, to about 900 degrees Celsius to about 1000 degrees Celsius. Above 650 degrees Celsius the aluminum will begin to melt, and below 600 degrees Celsius, carbon nanotube production may be impaired compared to production at a higher temperature. The presence of remaining aluminum bulk limits the maximum temperature. Otherwise a full range of about 400 degrees Celsius to about 1200 degrees Celsius may be used. As an example, if a different material is used, such as tungsten, a higher temperature than 650 degrees Celsius may be used because the melting point of this material is higher than aluminum.

In an embodiment, the aluminum bulk will be removed, which will leave a thin aluminum oxide film on the bottom side, such that the catalyst particle is not exposed (or the single-walled carbon nanotubes will grow from that side and not into the pore itself). After synthesis, the thin aluminum oxide film or bulk aluminum is removed and the aluminum oxide membrane will have the ability to metal connect to each side of the carbon nanotube.

In another embodiment of the invention, carbon nanotubes are synthesized before incorporation into the device. The carbon nanotubes are synthesized beforehand in bulk by any competent method such as CVD, arc-discharge, laser ablation method, or the like, or combinations of these, or any other method. Then the carbon nanotubes are transferred into the pores of the structure.

In one embodiment of the present invention, a method is as follows. Fabricate pores and the aluminum oxide film, and then remove the aluminum bulk and expose each side of the pores. As discussed above, in an embodiment, the pores and aluminum oxide may be formed at the same time as the aluminum is being oxidized. Synthesize the carbon nanotubes. Then the carbon nanotubes are put in solution or suspension by any competent method. Flow a solution or suspension containing carbon nanotube through the pores such that it leaves carbon nanotubes in the pores with the ability to contact each side with metal electrodes.

More specifically, carbon nanotubes in solutions or suspensions are transferred to the pores as the liquid flows through the pores. Microfluidic methods may be used. Any unwanted or extraneous carbon nanotubes or portions of carbon nanotubes are removed by any competent method such as chemical, electrical, or mechanical methods, or the like.

While in solution, the carbon nanotubes can further be separated to enrich the semiconducting content and optimize the length and diameter. For example, the carbon nanotubes may be separated by size, length, or electrical characteristics. In one implementation, semiconducting carbon nanotubes are separated from metallic carbon nanotubes. Therefore, using this approach, it is possible to get a higher concentration of semiconducting carbon nanotubes than is possible by synthesis alone. The solution or suspension can also be optimized for carbon nanotubes of a desired diameter and length. The diameter of the carbon nanotube will determine the semiconducting band gap size. The length of the carbon nanotubes should be at least as long as the pore length.

The junctions can be formed during synthesis, after synthesis but before transfer to the pores, or after transfer to the pores. The first and second electrodes can then be made on each side of the carbon nanotubes and porous structure.

A first and second electrode are placed so that multiple carbon nanotubes are connected in a vertical fashion. For instance, the first electrode is placed on one side of the template or structure, and the second electrode is placed on the other, e.g., opposing or opposite, side. The carbon nanotubes have diameters that do not significantly change along the length of the nanotube. For example, in some embodiments, the diameters of each of most or substantially all of the nanotubes deviates by no more than about a desired tolerance. For example, in one embodiment, the diameters of each of most or substantially all of the nanotubes deviates by no more than about one nanometer, in another embodiment by no more than about 0.5 nanometer, or in another embodiment by no more than about 0.1 nanometer.

In an embodiment of the invention, the carbon nanotubes are cylindrical nanotubes having at most two ends. These may be referred to as a first end and a second end. One end is connected to one electrode and the other end is connected to another electrode.

In other embodiments, the carbon nanotubes may have more than two ends, such as Y shaped, X shaped, and other multibranched nanotubes. A Y-shaped carbon nanotube may have a first end, second end, and third end. An X-shaped carbon nanotube may have a first end, second end, third end, and fourth end. A junction of the invention may be at a meeting point of the branches or within any one of the branches, or both.

In an embodiment of the invention, the carbon nanotubes have at least one junction which joins two segments of the nanotubes. One or more additional electrodes (e.g., gates) may be added to modulate the properties of at least some portion of the carbon nanotubes. Each carbon nanotube in a pore may have a single or multiple junctions. If a carbon nanotube has a single junction, this junction may define two segments of the nanotube with different electrical or physical properties or characteristics. A carbon nanotube of the invention may have more than one junction, and then there will be more than two segments of the nanotube having different electrical or physical properties. There may be any number of segments, such as two, three, four, five, six, seven, eight, nine, ten, eleven, twelve, thirteen, or fourteen or more. If there are n junctions, then there will be n+1 segments, where n is an integer 1 or greater. Each segment may have different electrical properties from each other, or may have different properties from an adjacent segment.

In an embodiment of the invention, the length of each segment may be equal. For example, the junction may be in approximately a middle or center of the length nanotube. Then the segments will be approximately equal in length. However, in other embodiments of the invention, a length of each segment of a nanotube may be any length and vary from other segments of the same nanotube. The sum of the lengths of the segments will equal the length of the nanotube. For example, if a nanotube or pore is a unit length of 1, a segment may be 0.4 of the nanotube, while another segment is 0.6 of the segment. For a nanotube, a segment may be 0.55 and another segment may be 0.45. For a nanotube, a segment may be 0.33 and another segment may be 0.67. For a nanotube, a segment may be 0.10 and another segment may be 0.90. For a nanotube, a segment may be 0.33, another segment may be 0.25, and another segment may be 0.42. For a nanotube, a segment may be 0.25, another segment may be 0.50, and another segment may be 0.25.

In a further embodiment of the invention, a carbon nanotube may have continuously varying or graded properties or characteristics the entire length (or for a segment) of the nanotube. For example, at one end of the carbon nanotube, the doping may be p++ and then along carbon nanotube, the doping will decrease according to a gradient until the other end of the carbon nanotube, which will have p doping. Another example of a graded nanotube is that a peak (or trough) in doping occurs in a middle or other position of the segment and increases (or decreases) from that point to the ends of the segment. There may be multiple peaks or troughs in a nanotube.

The grading or variation of a carbon nanotube along its length may be according any relationship or function, such as mathematical, continuous, discontinuous, periodic, constant, monotonic, algebraic, transcendental, rational, irrational, linear, polynomial, quadratic, cubic, geometric, trigonometric, exponential, logarithmic, or any other relationship or function. A nanotube segment with any of these relationship or function may be may be combined in any a segment with any other function or relationship. These may be combined with any other property or characteristic such as doping type, doping type, chirality, material type, semiconducting or nonsemiconducting, metallic or nonmetallic, and defect density.

As examples, one segment of a nanotube may be linear while another segment is geometrical. One segment of a nanotube may be linear while another segment is constant. One segment of a nanotube may be linear while another segment is exponential. One segment of a nanotube may be logarithmic while another segment is discontinuous. One segment of a nanotube may be linear while another segment is exponential.

As even further examples, one segment may be p doped according to a constant function while another is n doped according to a linear function. One segment may be p doped according to a linear function while another is n doped according to a linear function. One segment may be p doped according to a constant function while another is p+ doped according to a linear function. One segment may be n doped according to a constant function while another is n+ doped according to a linear function.

A junction may define two segments with different electrical properties, such as a p-n junction or a junction between segments with different p or n doping concentrations. The junction may join conductive segment with a semiconducting segment, or two semiconducting segments with different band gaps. A junction may be formed by a split gate. For example, the split gate may form a p-n junction.

For a nanotube, there may multiple segments (or layers) of different characteristics, such as n doped segment, p doped segment, and n doped segment, and so forth. For a nanotube, there may be a p+ segment, p++ segment, and p+ segment, and so forth. For a nanotube, there may be an n+ segment, p segment, and p++ segment, and so forth. For a nanotube, there may be a p-type segment and an n-type segment. For a nanotube, there may be a p-type segment and a p+ type segment. For a nanotube, there may be semiconducting segment, conductive segment, and semiconducting segment, and so forth. For a nanotube, there may be a first nanotube segment with a first band gap and a second nanotube segment with a second band gap.

Furthermore, two segments may have different carrier concentrations, different chiralities (e.g., there may be two segments with different types of metallic tubes), conductance, physical properties, defect densities, crystallinities, qualities, or purities. A segment may be metallic or semimetallic, and a segment may be semiconducting.

Therefore, for a nanotube, there can be any number of segments with any combination of characteristics. Any two segments of the same nanotube may have the same characteristics, but may be separated from each other by one or more segments with different characteristics. A device of the invention may be made up of any number of carbon nanotubes with segments of different characteristics. These carbon nanotubes will be connected in parallel by the electrodes.

This device is especially suited for use as a diode, rectifier, silicon controlled rectifier, thyristor, and other similar and related devices. The device is capable of high current densities, high power, and efficient power delivery. There are large densities of possible connections, and it is not necessary for every pore to contain a functioning carbon nanotube with junction device. The redundancy allows for defects, failures, and low yields. The device may be configured to obtain significantly higher current densities and power capabilities than is currently conventionally available with semiconductor technology to obtain increased performance, suitable for a variety of power applications.

During operation of the device, one electrode is connected to one node of a circuit and the other electrode is connected to another node of the circuit. Depending on the voltage on each electrode, current will from one electrode to the other electrode under the appropriate circumstances. For example, then the device is a p-n junction, the device will operate as a diode. Above a certain threshold voltage, the device will conduct, but below that voltage, the device will not conduct. And when the device is reverse biased, it will not conduct, unless in a reverse breakdown situation. Depending on the characteristics of the nanotube segments used in forming the device, the I-V characteristic of the device can be altered as desired.

Various techniques may be used to fabricate a device of the invention. Segments and junctions are created by treating different regions or portions of a nanotube differently. Nanotube portions are treated differently to obtain different characteristics. These characteristics may be different electrical characteristics or different physical characteristics. Although the segments have different characteristics, the nanotube with the junction is a homogenous structure.

Some techniques to fabricate a device of the invention are described in more detail below. A technique may involve protecting a portion of a carbon nanotube with a material such as a polymer or other isolating material. The exposed portion of the carbon nanotube will be exposed to a gas, liquid, or other analyte which is will alter the characteristics of the exposed portion of the nanotube. For example, the analyte may be rich in n+ or p+ ions, so that the exposed portion or region of nanotube will become doped with such an ion.

Another technique involves exposing or surrounding different portion or regions of a nanotube to different polymers, gases, or analytes so that the different portions take on different characteristics. For example, pores may be filled with two or more different polymers, and the nanotube will develop characteristics based on the polymers they are surrounded by or exposed to. One portion of a tube may be exposed to a gas while another portion is protected or isolated from the gas.

Another technique involves using electrostatics or other conditions. An example is to use a charged gas or other analyte, and then using a gate or electrode to cause this charged analyte to surround a portion of a nanotube, but not the entire nanotube. Then the portion of the nanotube will take on characteristics based on the charged analyte to which it is exposed.

The devices may have gates or may not have gates. The nanotubes may be single-walled or multiwalled nanotubes. A portion of a nanotube may be semimetallic or metallic, and another portion of the same nanotube may be semiconducting. For a nanotube with a junction, a diameter of the nanotube may not vary significantly on either side of the junction. The diameter of such a nanotube may be within about 0.1 or 0.2 nanometers on either side of the junction. The diameter of such a nanotube may be within about 0.1 or 0.2 nanometers for the entire length of the nanotube. A typical diameter of a single-walled carbon nanotube is about 1 nanometer to 3 nanometers. A typical diameter (i.e., outside diameter) of a multiwalled carbon nanotube may be 10 nanometers to 20 nanometers.

FIG. 12 shows a further embodiment of the invention. This embodiment is similar to that shown above. The device structure further includes a substrate connected to the bottom electrode. The structure with pores is supported by a substrate and a significant number of the pores extend all the way to the substrate. This substrate may provide further support the structure and in some embodiment, may act as a heat sink to help dissipating heat of the device when it operates.

As described above, carbon nanotubes can be synthesized within the pores or transferred to the pores. The substrate may be coated with a conductive layer. The substrate or conductive layer on the substrate may be coated with effective catalyst for carbon nanotube synthesis. Direct synthesis of carbon nanotubes within the pores can use any competent method. In one embodiment of the present invention, catalyzed chemical vapor deposition is used. The catalyst may be predeposited at the bottom of the pores or deposited after pore formation. In another embodiment, chemical vapor deposition is used without the presence of a catalyst.

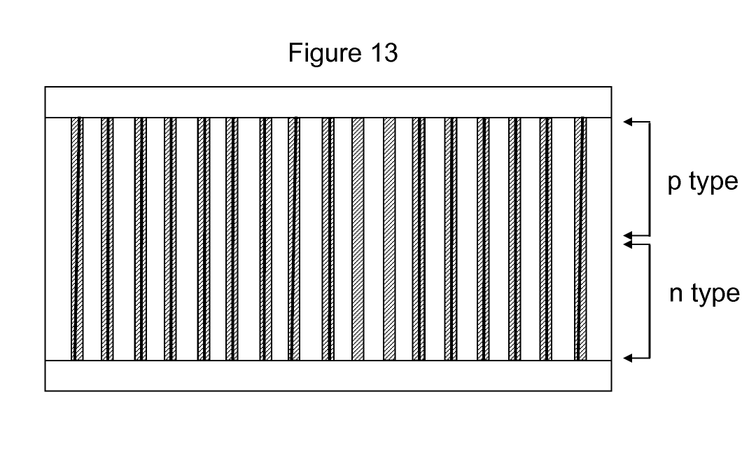

FIG. 13 shows a cross-sectional view of a device indicating p-doped segments of the carbon nanotubes and n-doped segments. The nanotubes are electrically connected to both the first and second electrodes. Although shown the p and n segments are shown with approximately equal lengths in this figure, as has been discussed, the lengths of each segment may be different and selected as desired.

The first electrode is on one side of the porous structure and connects with one end of plurality of the carbon nanotubes. The second electrode is on the other side of the porous structure and connects with the other end of a plurality of the carbon nanotubes. The carbon nanotubes are then electrically connected and can function as a current carrying device. The figure schematically illustrates the carbon nanotubes as having a p doped segment and an n doped segment, so as to form p-n junctions in a multitude of the carbon nanotubes.

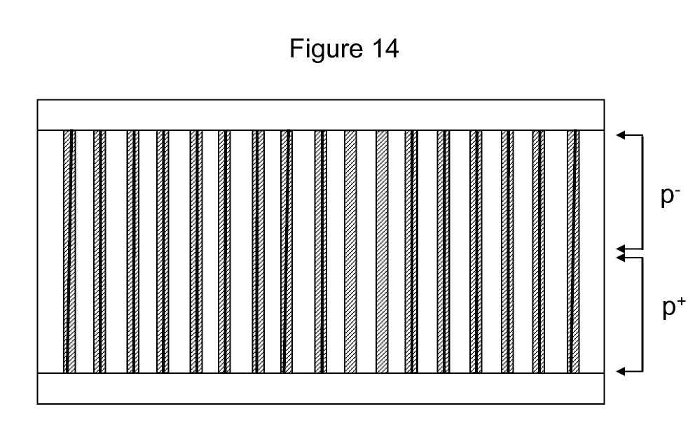

FIG. 14 shows a cross-sectional view of a device indicating lightly p-doped segments of the carbon nanotubes and more heavily p-doped segments. The nanotubes are electrically connected to both the first and second electrodes. Alternatively, the device could also have n-type segments in the place of the p-type segments (not illustrated). For example, one segment may be n+ and another segment may be n−. Although shown the different segments are shown with approximately equal lengths in this figure, as has been discussed, the lengths of each segment may be different and selected as desired.

The first electrode is on one side of the porous structure and connects with one end of plurality of the carbon nanotubes. The second electrode is on the other side of the porous structure and connects with the other end of a plurality of the carbon nanotubes. The carbon nanotubes are then electrically connected and can function as a current carrying device. The figure shows the carbon nanotubes as having a lightly doped p segment and a more heavily doped p segment, so as to form p− and p+ junctions in a multitude of the carbon nanotubes. Alternatively, lightly doped n segments and heavily doped n segments could be used so as to form n− and n+ junctions. These types of junctions between segments with different dopant concentrations may be particularly useful as Schottky type diodes or rectifiers.

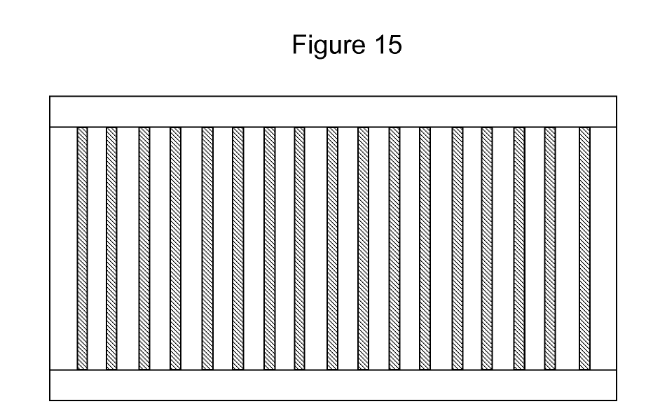

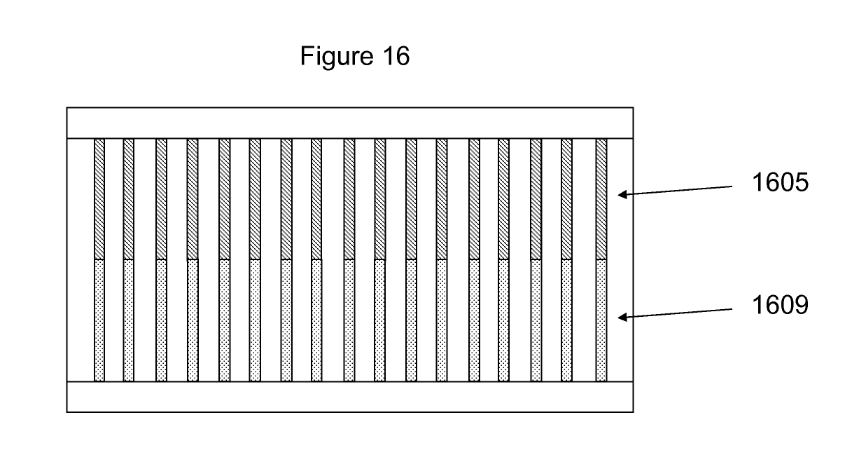

FIG. 15 shows a cross-sectional view of the pores filled with a material. FIG. 16 illustrates multiple materials filled into the pores in a sequential method. More specifically, there are two materials 1605 and 1609 in each pore. However, in further embodiments of the invention, there may be any number of materials, such as three, four, five, six, seven, or eight or more.

In fabricating or processing a device of the invention, an optional filler may be added to the device. These figures may show the structure during intermediate steps in processing of a device of the invention. The filler may be used to passivate, protect, or stabilize the carbon nanotubes. The filler may also be useful in doping all or part of the carbon nanotubes. FIG. 16 shows two filler materials added sequentially. For instance, the first filler may increase or maintain p doping, and the second filler may have or maintain n doping. In this way, p-n junctions can be formed. In an embodiment, the filler may be added during a processing step, and then removed during a subsequent processing step.

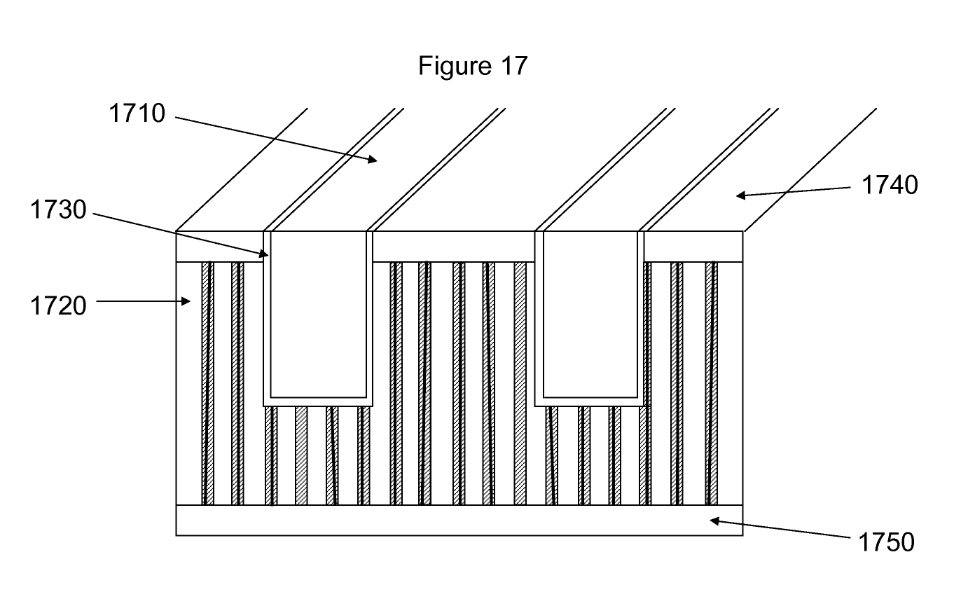

FIG. 17 shows a perspective view of device of the invention where a gate electrode is added to the structure, so the device will operate as a transistor device. The transistor device structure has a gate 1710, where the gate is extends at least into the insulating layer 1720. A thin layer 1730 insulates the conductive gate from the top 1740 and bottom 1750 electrodes.

Further details on carbon nanotube transistor devices may be found in U.S. patent application U.S. patent application Ser. No. 11/162,548, filed Sep. 14, 2005, which is incorporated by reference. Any of the techniques described in this previous patent application may be applied or used in combination with devices and techniques having carbon nanotubes with multiple electrical properties as described in this patent application. A carbon nanotube transistor may be made up of carbon nanotubes having any number of segments with different characteristics.

A gate electrode may be fabricated either on one (shown) or both sides (not shown) of the porous structure. When gate electrodes are formed from both sides of the porous structure, the gate electrodes from each side may be interdigitated with each other. In an alternative implementation, the gate electrodes on both sides may be mirror images of each other.

As discussed above, any number of individual gate electrode elements may be connected together to effectively become one large gate. For example, if two gate electrode elements are connected together, the effective gate size is about two times the size of the gate electrode. If n gate electrodes are connected together, the effective gate size will about n times the size of the gate electrode. For a device, there may be two or more gates. This is referred to as a split-gate design. For example, some gate electrodes are linked together as one group, and other gate electrodes are connected together as another group.

A voltage on the gate electrode is used to modulate the electrical properties of the carbon nanotube device. The gate electrode is placed near enough to the carbon nanotubes in order to be an effective gate for the application. The gate electrode can also be etched or other formed extending into the porous structure so for greater effectiveness.

The figure shows the gate as partially extending into the porous structure. According to one embodiment, a split gate (i.e., two gates that are not electrically connected but nearby) may be used. In this embodiment, the split gate may form p-n junctions.

The gate region 1710 is etched, deposited, or otherwise formed into the aluminum oxide structure so as to be more effective at gating the length of the carbon nanotubes. A depth of the gate region may be the entire length of the porous structure (e.g., through the source electrode and up to or adjacent the drain electrode), or the depth may be any portion of the length of the porous structure. For example, the depth of the gate may be 5 percent, 10 percent, 20 percent, 30 percent, 40 percent, 50 percent, 55 percent, 60 percent, or a greater percentage of the length of the porous structure. The depth may be less than 20 percent, less than 30 percent, less than 40 percent, less than 50 percent, and other percentages.

When processing a device of the invention, a conductive layer if formed on a surface of the porous structure. This conductive layer may be for the source or drain electrode region. The conductive layer may be patterned to etch openings for the gate. To etch an aluminum oxide structure with pores, a reactive ion etcher (RIE) may be used. A reactive ion etcher is a form of dry etching. One example for the gases used for reactive ion etching is argon. Another example is argon and SF₆. The gases used may be argon, fluorides (like SF₆), or chlorides, oxygen, or combinations of these.

For the distances or depths etching into the porous structure, in one embodiment, the trench depth is about 5 nanometers or 50 Angstroms. If the total thickness is 1 micron or 10,000 Angstroms, 50 Angstroms would be a depth of 0.5 percent. In such an embodiment, the trench depth would be at least 0.5 percent. In another embodiment, the depth will be about 10 nanometers, 100 Angstroms, or a one percent depth. In another embodiment, the depth will be about 50 nanometers, 500 Angstroms, or a five percent depth. In another embodiment, the depth will be about 100 nanometers, 1000 Angstroms, or a ten percent depth. In a further embodiment, the depth will be about 500 nanometers, 5000 Angstroms, or a fifty percent depth. In a further embodiment, the depth will be about 1000 nanometers, 10,000 Angstroms, or a one-hundred percent depth.

The etch rates may be dependent on the trench size or more particularly, a width of a line. Smaller lines or openings may etch more slowly than larger ones, so this will affect the depths versus lithography line dimensions.

Also, the gate region is shown as a rectangular shape in FIG. 17. However, in other implementations of the invention, the gate may be in any shape such as a polygon, triangle, trapezoid, circle, ellipse, oval, or some combination of shapes.

Furthermore, according to a technique of the invention, the trench is formed into the porous structure by etching by chemicals, plasma, laser, mechanical means, micro-electro-mechanical systems (MEMS), or other technique. An isolating material is deposited in the trench such as aluminum oxide, silicon oxide, zirconium oxide, hafnium oxide, or another insulating material. This insulating material will prevent the gate material from shorting out any carbon nanotubes. Then gate material 1710 is deposited in the trench. The gate material may be deposited using sputtering, evaporation, or other technique.

Another consideration for selecting a gate depth is the type of transistor being fabricated. If the device is a depletion mode transistor, the depth of the gate may be less than if the device is an enhancement mode transistor. This is because a depletion mode transistor is normally on. Therefore, to turn the depletion mode transistor off, the gate has to turn off any relatively small portion of the channel or carbon nanotube. In contrast, for an enhancement mode transistor, the gate should turn on the entire channel for the transistor to be fully on.

After device fabrication, the carbon nanotube transistor device is mounted and packaged in order to achieve overall mechanical, electrical, and thermal quality and stability as a final product.

In operation, a voltage is applied to the gate electrode to modulate the electrical properties of the semiconducting carbon nanotubes. The gate electrode is placed near enough in proximity to the carbon nanotubes in order to be an effective gate. In some embodiments of invention, an effective gate for the transistor will be just a portion of the semiconducting carbon nanotubes—that is, the portion nearest the gate electrode. In other words, when a voltage is applied to the gate, there will be an electric field in the porous structure. The field strength of this electric field will decrease as a distance from the gate increases. Therefore, carbon nanotubes that are closer to the gate will be more influenced by the gate.

Depending on the characteristics of the semiconducting carbon nanotubes, the transistor may be enhancement, depletion, native, or other type of transistor. This will adjust the characteristics of the transistor. For example, a depletion mode carbon nanotube transistor passes current until it is turned off, while an enhancement mode carbon nanotube transistor normally impedes current until it is triggered to turn on. To obtain the desired transistor characteristics, the carbon nanotubes may be adjusted during the processing. For example, the carbon nanotubes may be doped with certain ions or absorbed molecules to adjust their characteristics.

In an embodiment, the pores may be filled after tube growth. For example, in an embodiment where the carbon nanotubes do not fill the entire pore, the remaining area within the pores may be partially or completely filled with a material. Examples of the material may be an insulator, metal, semiconductor, or polymer. This material may be used to passivate, protect, stabilize, or modify, or combinations of these, the properties of the carbon nanotubes. For example, a polymer may be used to coat the nanotubes to give the nanotubes a particular type of doping. Also, the polymer may be chemically modified during processing.

In a further embodiment, a material may be added to fill in at least some portion of the open area within the pores. In particular, as discussed above, the carbon nanotube is smaller than a diameter than the pore. This “empty” space between the nanotube and pore walls may be filled or coated with a material such as an insulator, metal oxide, polymer, or other material.

The empty space may be filled with multiple materials or layers of different materials. One layer may be an insulator, metal oxide, polymer, or other nonconducting layer. Another layer may be a metal, semiconductor, polysilicon, polymer, or other conducting layer. The nonconducting layer would be considered nonconducting relative to the conducting layer. The insulator would insulate the carbon nanotube from other materials, which may be conductive materials. There may be two, three, four, five, six, seven, eight, or more layers within each pore. Some of the layers may be the same of different, in any combination as desired. For example, the layers may alternate between conductive and nonconductive.

Using multiple concentric layers of different material, individual pores may be used to form a transistor device. In a pore will be a carbon nanotube, which will serve as a channel region of the transistor. Surrounding at least a portion of the carbon nanotube will be a relatively thin insulating layer such as an oxide. Further, surrounding this oxide will be a conductive layer such as metal, polysilicon, other conductor. This layer will serve as a gate electrode of the transistor. In such an embodiment of the invention, the pore diameters are selected to permit the multiple layers to be fabricated and connected to, and the pore density will be affected accordingly. The porous structure may have many numbers of these transistors, and each may be operated independently of another, or two or more of the transistors may be connected together. Or a group or all the transistors of the porous structure may be connected together to be operated as a single large transistor.

In a specific embodiment, the carbon nanotube are formed or placed in the pores before forming the layers. Carbon nanotubes are synthesized or transferred to uncoated pores. The carbon nanotubes are isolated with oxide or similar insulator. Then the gate material is added. The source or drain, or both, may be contacted before or after the gate if added.

Furthermore, the carbon nanotube may be resting in place on one side of the pore walls. Then, the insulating layer and any other layers will fill the pore and almost surround the entire length of the nanotube, but not the part of the nanotube that is in contact with the original porous structure. If desirable, the portion of the nanotube that is touching the porous structure may be removed. For example, this portion may be removed by etching, chemical mechanical polishing, electropolishing, grinding, or other removal techniques. What will be left will be the one or more layers and the carbon nanotube without the portion touching the porous structure.

In another specific embodiment, the carbon nanotubes are formed or placed in the pore after the layers are formed. To fabricate this embodiment of the invention, one technique is, after fabricating the pores, to form in or coat the pores with a conductive material, which will become the gate. Then an insulating coating is added, which will be the gate oxide. Then carbon nanotubes are synthesized or transferred, in a fashion as discussed elsewhere in this patent, to the coated pores. Connections will then be made to the transistors.

Two or more carbon nanotube transistors may be manufactured on the same porous structure. These carbon nanotube transistors on the same structure may operate independently of each other, or may be electrically connected to each other in some fashion to form a circuit, an integrated circuit of carbon nanotube transistors. Carbon nanotube transistors of the invention may be integrated with other non-carbon-nanotube devices, such as NMOS, PMOS, or BJT transistors, diodes, resistances, capacitances, inductances, impedances, and others formed on the same porous structure, or the non-carbon-nanotube devices may be on a separate structure, such as a semiconductor substrate. These separate structures (which may be referred to as dies) may be packaged together in a single package, or may be separately packaged.

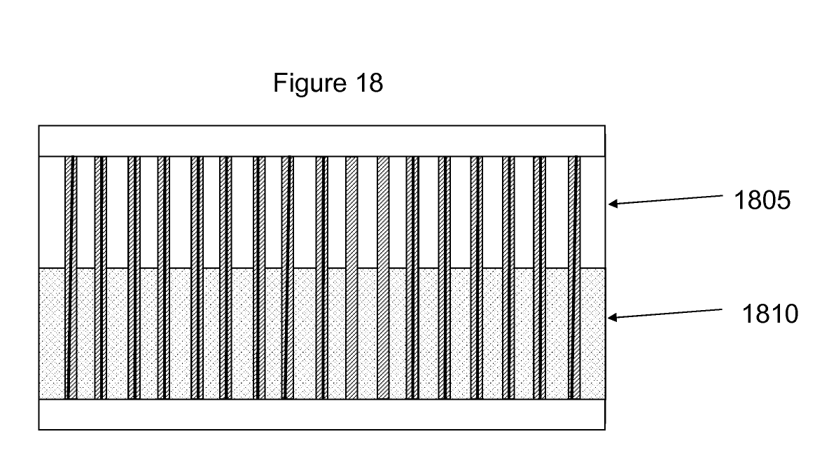

FIG. 18 shows a cross-sectional view of a device which incorporates a first insulating layer with pores 1805 and a second material with pores 1810, where the pores were transferred into the second material by the pore pattern of the first insulating layer.

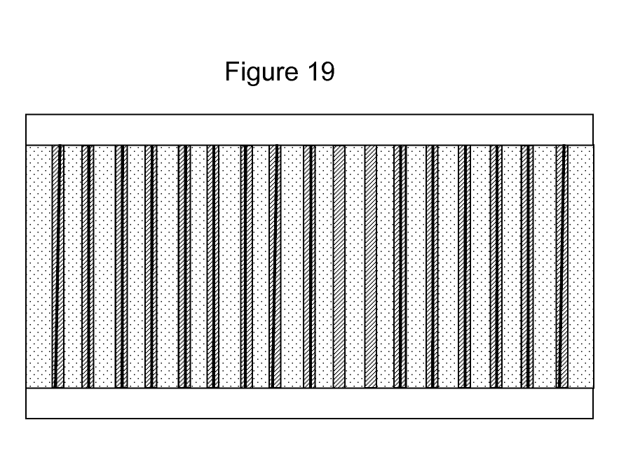

FIG. 19 shows a cross-sectional view of a device where the first insulating layer (see 1810 in FIG. 18) is removed after pore transfer and the second material with pores remains.

In reference to FIGS. 18 and 19, the pores may be transferred from a first porous structure to another material. The first material may include aluminum oxide, titanium oxide, niobium oxide, tantalum oxide, zirconium oxide, or combinations of these, and that has been made porous as discussed elsewhere in this application. The pattern of pores is transferred to the second material by any competent method. For example, the transfer of pores can use the first porous structure as a mask and etching through the pores into the other medium, where the etching can be through chemical, mechanical, or electrical methods known in the art, e.g., plasma etching, dry etching, wet etching, reactive ion etching. FIG. 18 shows a device where the first porous structure remains.

FIG. 19 shows a device where the first porous structure is removed before completing the formation of the device.

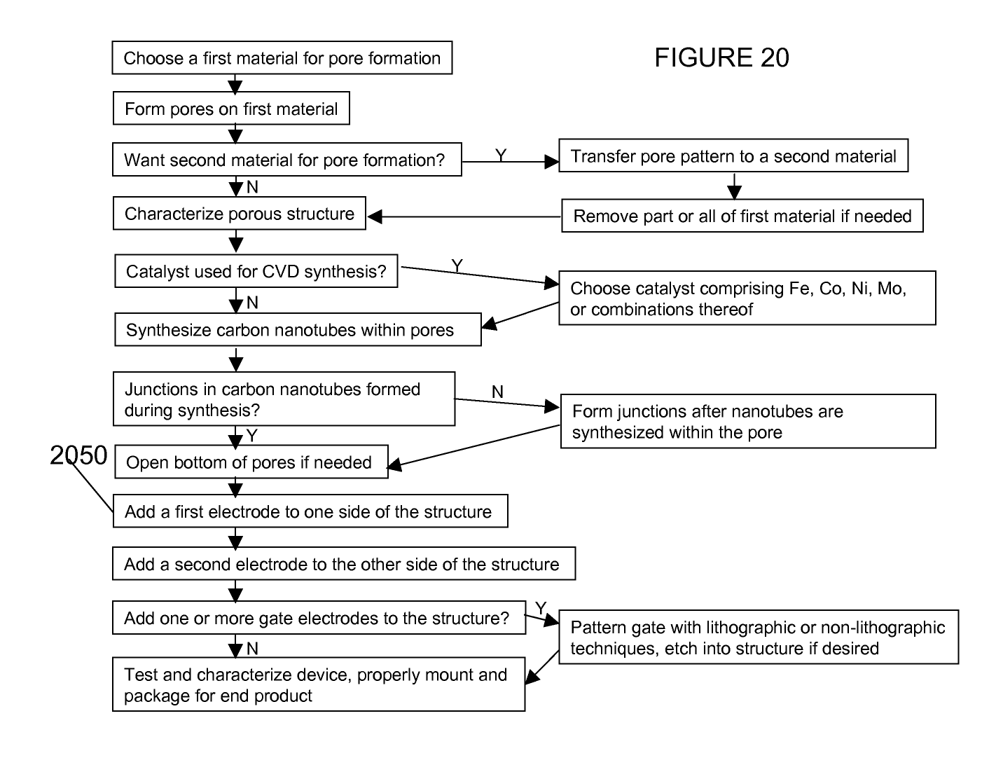

FIGS. 20, 21, and 22 show flow diagrams of techniques of the invention. In the these flow diagrams, any and every path through a (composite) schematic flow diagram is a method, and any and every subset of alternate paths can be alternate paths through a multipath method.

FIG. 20 shows a flow diagram for some embodiments of the present invention that are methods for device fabrication using direct synthesis of carbon nanotubes within pores by chemical vapor deposition (CVD).

More specifically, the method includes:

(1) Choose a first material for pore formation.
(2) Form pores on first material.
(3) Want second material for pore formation? If yes, go to (4), otherwise (6).
(4) Transfer pore pattern to a second material.
(5) Remove part or all of first material if needed.
(6) Characterize porous structure.
(7) Catalyst used for CVD synthesis? If yes, go to (8), otherwise (9).
(8) Choose catalyst including Fe, Co, Ni, Mo, or combinations of these.
(9) Synthesize carbon nanotubes within pores.
(10) Junctions in carbon nanotubes formed during synthesis? If no, go to (11), otherwise (12).
(11) Form junctions after nanotubes are synthesized within the pore.
(12) Open bottom of pores if needed.
(13) Add a first electrode to one side of the structure. This is box 2050 in FIG. 20.
(14) Add a second electrode to the other side of the structure.
(15) Add one or more gate electrodes to the structure? If yes, go to (16), otherwise (17).
(16) Pattern gate with lithographic or nonlithographic techniques, etch into structure if desired.
(17) Test and characterize device, properly mount and package for end product.

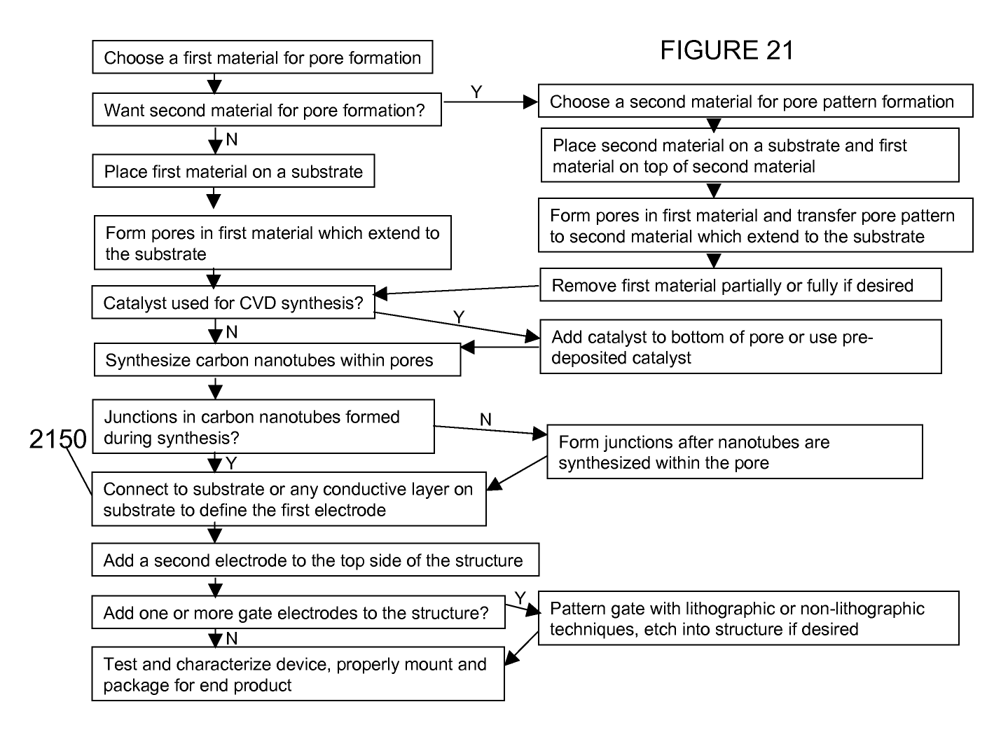

FIG. 21 shows a flow diagram for some embodiments of the present invention that are methods for device fabrication using chemical vapor deposition (CVD) synthesis of carbon nanotubes within pores, where a substrate is in addition to the porous structure with a plurality of pores.

More specifically, the method includes:

(1) Choose a first material for pore formation.
(2) Want second material for pore formation? If yes, go to (3), otherwise (7).
(3) Choose a second material for pore pattern formation.
(4) Place second material on a substrate and first material on top of second material.
(5) Form pores in first material and transfer pore pattern to second material which extend to the substrate.
(6) Remove first material partially or fully if desired. Go to step (9).
(7) Place first material on a substrate.
(8) Form pores in first material which extend to the substrate.
(9) Catalyst used for CVD synthesis? If yes, go to (10), otherwise (11).
(10) Add catalyst to bottom of pore or use predeposited catalyst.
(11) Junctions in carbon nanotubes formed during synthesis? If no, go to (12), otherwise (13).
(12) Form junctions after nanotubes are synthesized within the pore.
(13) Connect to substrate or any conductive layer on substrate to define the first electrode. This is box 2150 in FIG. 21.
(14) Add a second electrode to the top side of the structure.
(15) Add one or more gate electrodes to the structure? If yes, go to (16), otherwise (17).
(16) Pattern gate with lithographic or nonlithographic techniques, etch into structure if desired.
(17) Test and characterize device, properly mount and package for end product.

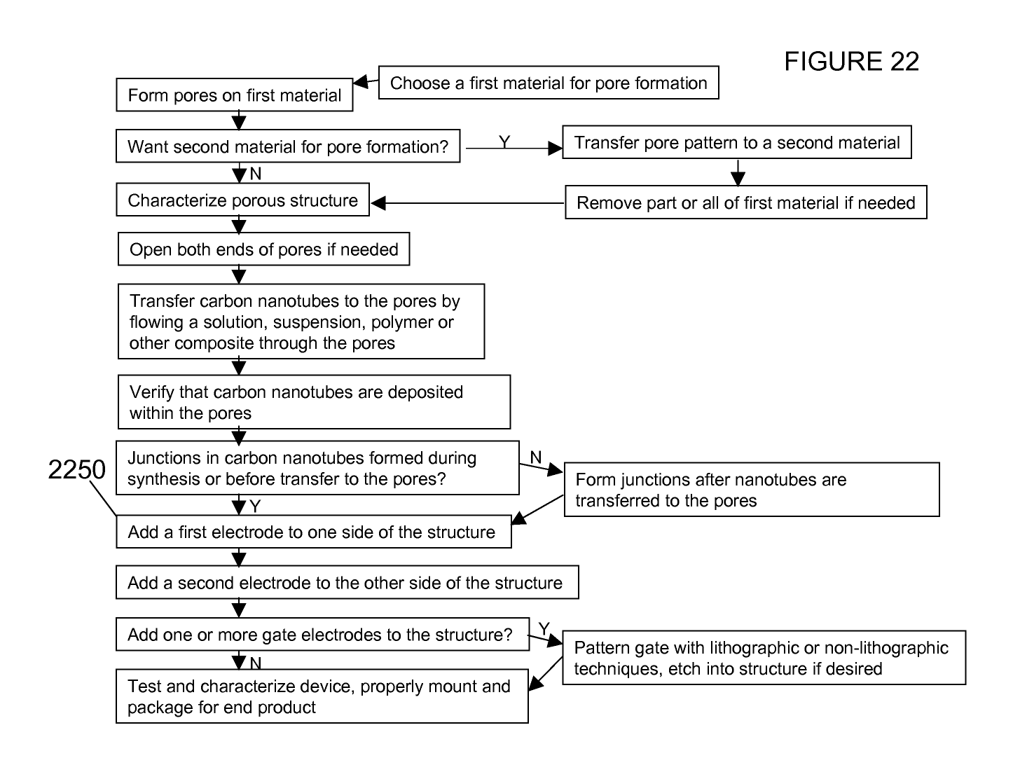

FIG. 22 shows a flow diagram for some embodiments of the present invention that are methods for device fabrication using carbon nanotubes that are transferred to the pores, e.g., by liquid deposition methods.

More specifically, the method includes:

(1) Choose a first material for pore formation.
(2) Want second material for pore formation? If yes, go to (3), otherwise (5).
(3) Transfer pore pattern to a second material.
(4) Remove part or all of first material if needed.
(5) Characterize porous structure.
(6) Open both ends of pores if needed.
(7) Transfer carbon nanotubes to the pores by flowing a solution, suspension, polymer or other composite through the pores.
(8) Verify that carbon nanotubes are deposited within the pores.
(9) Junctions in carbon nanotubes formed during synthesis or before transfer to the pores? If no, go to (10), otherwise (11).
(10) Form junctions after nanotubes are transferred to the pores.
(11) Add a first electrode to one side of the structure. This is box 2250 in FIG. 22.
(12) Add a second electrode to the other side of the structure.
(13) Add one or more gate electrodes to the structure? If yes, go to (14), otherwise (15).
(14) Pattern gate with lithographic or nonlithographic techniques, etch into structure if desired.
(15) Test and characterize device, properly mount and package for end product.

Note that, in each of the FIG. 20, 21, or 22, all steps shown before or above the steps 2050, 2150 or 2250, respectively, can also be referred to as a step of constructing a structure having pores, with carbon nanotubes in the pores, the nanotubes having junctions. In some embodiments, preferably the nanotubes are mostly or substantially all nonbranching or nonsignificantly-diameter-varying nanotubes, or both.

In one embodiment of the present invention, carbon nanotubes are directly synthesized within the pores of the insulation structure. At least some of the carbon nanotubes have lengths of about equal or greater than the length of the pore. The insulating structure with pores is formed by anodization of a metal, e.g., aluminum, titanium, niobium, tantalum, zirconium, or combinations of these. The anodization process often leaves one end of the pore closed, e.g., by a thin barrier layer, e.g., by a thin barrier layer and remaining (not completely anodized) metal. The carbon nanotubes can by synthesized before or after any barrier layer is removed. The barrier layer can be removed by any competent means as known in the art, e.g., chemical, mechanical, or electrical methods, or combinations of these.

The at least one junction in the carbon nanotubes can be formed during or after synthesis of the carbon nanotubes. The synthesis of carbon nanotubes may occur with or without the presence of catalyst. Chemical vapor deposition may be used for the synthesis of the carbon nanotubes. Any unwanted, noneffective, or extraneous carbon nanotubes or portions of these may be removed by any competent method, e.g., chemical, electrical, or mechanical methods, or the like, or any other methods known in the art. A first electrode is placed on one side of the structure and connects to multiple of the carbon nanotubes. A second electrode is placed on the other, e.g., opposing, side of the structure and connects to multiple of the carbon nanotubes. The electrodes can be placed by any competent method as known in the art, e.g., deposition techniques known in the art including lithographic or nonlithographic techniques. The pores may be partially or completely filled with a material. This material may be used to passivate, protect, stabilize, or modify the properties of the carbon nanotubes, or combinations of these.

In one embodiment of the present invention, the insulating structure with a number of pores is on a substrate. The substrate may be a semiconductor, conductor, or insulator. The substrate may be used only for mechanical support or it may be used for electrical or thermal advantages. In one embodiment, the substrate is one of the electrodes that connects to multiple of the carbon nanotubes. The substrate is coated with metal, e.g., aluminum, titanium, niobium, tantalum, zirconium, or combinations of these, by methods known in the art. For instance, the metal may be deposited by sputtering, thermal evaporation, or electron beam evaporation.

The metal is anodized which creates a plurality of pores, where multiple of the pores extend to the underlying substrate. Prior to the deposition of the metal to be anodized, the underlying substrate may be coated with a conducting layer to define or improve the conductivity of the bottom electrode, e.g., molybdenum, tungsten, or other conductive layer.

An additional catalytic deposition step may be used after said conducting layer on underlying substrate is deposited. The catalytic layer may also be applied directly to the underlying substrate in the absence of said conducting layer. The catalyst is exposed after the formation of the pores in the insulating layer, and may be used for the synthesis of carbon nanotubes.

In another embodiment, the catalyst is deposited after the formation of the pores. In yet another embodiment, the synthesis of carbon nanotubes does not require the catalyst. The at least one junction in the carbon nanotubes can be formed during or after synthesis of the carbon nanotubes. At least some of the carbon nanotubes have lengths of about equal or greater than the length of the pore. Any unwanted, non-effective, or extraneous carbon nanotubes or portions of these may be removed by any competent method, e.g., chemical, electrical, or mechanical methods, or the like, or any other methods known in the art. The second electrode is placed on top of the insulating structure.

In one embodiment of the present invention, carbon nanotubes are synthesized before incorporation into the device. The synthesis can be by any competent method, for example, chemical vapor deposition, arc-discharge, or laser ablation, or the like, or any other technique known in the art. The at least one junction can be formed during the synthesis, after the synthesis but before incorporation into the device, or after incorporation into the device.

The carbon nanotubes can further be separated to optimize the nanotube characteristics for incorporation in the device, e.g., the electrical properties, lengths, diameters, defect concentration, and other properties. Carbon nanotubes in solutions, suspensions, or composites are transferred to the pores as the liquid flows through or into the pores. Microfluidic methods as known in current art may be used.

The insulating structure with pores may be a membrane where the majority of pores are open on both sides, or it may be supported by remaining material from the metal anodization process, or it may be on a substrate. At least some of the carbon nanotubes have lengths of about equal or greater than the length of the pore. Any unwanted, noneffective, or extraneous carbon nanotubes or portions of these may be removed by any competent method, e.g., chemical, electrical, or mechanical methods, or the like, or any other methods known in the art.

A first electrode is placed on one side of the structure and connects to multiple of the carbon nanotubes. A second electrode is placed on the other, e.g., opposing, side of the structure and connects to multiple of the carbon nanotubes. The electrodes can be placed by any competent method as is well known in the art, e.g., deposition techniques known in the art including lithographic or nonlithographic techniques. The pores may be partially or completely filled with a material. This material may be used to passivate, protect, stabilize, or modify the properties of the carbon nanotubes, or combinations of these.

In one embodiment of the present invention, the porous structure can be primarily made of an insulating material, where the pattern of pores is transferred to it by any competent method. The pattern of pores in the structure may be made by transfer from a first porous structure that comprises aluminum oxide, titanium oxide, niobium oxide, tantalum oxide, zirconium oxide, or combinations of these, and that has been made porous as discussed elsewhere in this application.

For example, the transfer of pores can use the first porous structure as a mask and etching through the pores into the other medium, where the etching can be through chemical, mechanical, or electrical methods known in the art, e.g., plasma etching, dry etching, wet etching, reactive ion etching. The first porous structure can remain, be partially removed, or be completely removed before forming the device.

In one embodiment of the present invention, the device is a diode, rectifier, silicon controlled rectifier, or thyristor comprising a structure that defines a plurality of pores, carbon nanotubes within at least some of the plurality of pores, at least one junction in multiple ones of the carbon nanotubes, a first electrode on a first side of the structure connecting to multiple ones of the carbon nanotubes, a second electrode on a second (e.g., opposing) side of the structure connecting to multiple ones of the carbon nanotubes, and where the carbon nanotubes have diameters that do not significantly change along the length of the nanotube.

The structure with pores may include aluminum oxide, titanium oxide, niobium oxide, tantalum oxide, zirconium oxide, silicon oxide, silicon nitride, yttrium oxide, lanthanum oxide, hafnium oxide, zinc oxide, silicon, gallium nitride, silicon carbide, gallium arsenide, plastic, polymer, glass, quartz, carbon, a metal, copper, a noble metal, or combinations of these. At least one gate electrode may be added to the device. In another embodiment, the structure that defines the plurality of pores may be used as a gate, e.g., in order to electrostatically modulate the properties of the device. In this embodiment, a thin insulating or protective layer may be added to the structure prior to the deposition or synthesis of carbon nanotubes.

In another embodiment of the present invention, the device is a diode, rectifier, silicon controlled rectifier, or thyristor comprising a structure with a plurality of pores, where the structure comprises at two or more layers (e.g., where the layers are of different materials). The layers may be insulating, semiconducting, or conductive. In one embodiment, there are two or more layers, where at least one is insulating and at least another is conductive.

The structure may be fabricated by forming a plurality of pores on a first layer and transferring it to additional layers. For instance, the first layer may include aluminum oxide, titanium oxide, niobium oxide, tantalum oxide, zirconium oxide, or combinations of these, where the pores are formed by any competent method known in the art, e.g., anodization methods. The pores may be transferred to additional layers by any competent method known in the art, e.g., etching through chemical, mechanical, or electrical methods, e.g., plasma etching, dry etching, wet etching, reactive ion etching.

In one embodiment of the present invention, the junctions are formed during synthesis of the carbon nanotubes. For example, the synthesis conditions, e.g., pressure, temperature, gas species, flow rates, or combinations of these may be changed at a time during the growth so as to form junctions. For example, dopants may be incorporated into portions of the carbon nanotubes by adding or increasing the concentration of dopant precursors at a time during the growth so as to form junctions.

In one embodiment of the present invention, the junctions are formed after the synthesis of the carbon nanotubes. The junctions can be formed by chemical, electrical, or mechanical methods known in the art. For instance, junctions can be formed based on controlled environmental exposure, ambient exposure, exposure to oxidative environments, intentional doping or coating, annealing, heating in vacuum, electrostatic doping, polymer coating, or combinations of these, e.g., to only a portion or segment of the carbon nanotube, e.g., where the remaining portion or segment is not affected as much or at all.

The junctions may define two or more segments with different properties, where the segments have different electrical, e.g., charge carrier type or concentration, band gaps, or conductivity, or physical properties, e.g., defect densities, chiralities, crystallinities, qualities, or purities. In one embodiment the junction is a p-n junction. In another embodiment the junction is between a lightly doped segment with a more heavily doped segment, where the dopant an n-type dopant or a p-type dopant. A device with this type of may be particularly useful as a Schottky diode.

In one embodiment, the carbon nanotubes are exposed to ambient, oxidative environments, or oxygen and multiple of the carbon nanotubes become p-type semiconductors. A portion or segment of the carbon nanotubes is passivated or stabilized with an organic coating, inorganic coating, polymer coating, silicon oxide, metal oxide, or combinations of these. The uncovered portion or segment is subjected to treatments that transform them into intrinsic or n-type semiconductors, e.g., annealing, heating in vacuum, intentional doping or coating, polymer coating, or combinations of these.

Thus, p-n junctions can be formed in a multitude of the carbon nanotubes. In another embodiment, an n type or intrinsic carbon nanotube is passivated or stabilized with an organic coating, inorganic coating, polymer coating, silicon oxide, metal oxide, or combinations of these. The uncovered portion or segment is subjected to treatments that transform them into p-type semiconductors.

In one embodiment of the present invention, the device is a diode or a rectifier. Carbon nanotubes are deposited or synthesized within the pores of an insulating structure. A first (cathode) and second (anode) electrode are placed on opposing sides of the insulating structure, and contact multiple ones of the carbon nanotubes. Multiple ones of the carbon nanotubes have p-n junctions within the pores. The junctions can be formed before or after deposition in the pores. The junctions can be formed by chemical or electrical methods known in the art, for example based on controlled environmental exposure, ambient exposure, exposure to oxidative environments, intentional doping or coatings, annealing, heating in vacuum, electrostatic doping, polymer coatings, or combinations of these.

The device according to the present invention includes large densities of possible connections, and it is not necessary for every pore to contain a functioning carbon nanotube device. The redundancy allows for defects, failures, and low yields.

In one embodiment of the present invention, 95 percent and higher of the carbon nanotubes have effective junctions. In another embodiment, 70 percent and higher of the carbon nanotubes are effective junctions. However, still lower percentages (e.g., at least 60 percent or even lower) can also be tolerated to obtain a working device.

In another embodiment of the present invention, the electrodes are made from electrical connecting multiple smaller electrodes, e.g., electrodes that are in direct contact with the carbon nanotubes are connected together to define the first or second electrode. For instance, the electrodes in direct contact with the carbon nanotubes may include a nanowire, nanoparticle, nanoribbon, or other nanoscale electrode, e.g., an electrode with a cross-sectional area of less than one square micron.

In one embodiment of the present invention, after device fabrication, the device is properly mounted and packaged in order to achieve overall mechanical, electrical, and thermal quality and stability as a final product.

Further example embodiments of the invention are described below:

EX-1. A device comprising:

an insulating structure that defines a plurality of pores;
carbon nanotubes within at least some of the plurality of pores;
at least one junction in multiple ones of the carbon nanotubes, where the junction defines two regions of different properties;
a first electrode on a first side of the structure connecting to multiple ones of the carbon nanotubes; and
a second electrode on a second (e.g. opposing) side of the structure connecting to multiple ones of the carbon nanotubes,
where the diameter of the carbon nanotubes does not significantly change on either side of a junction.

EX-2. A device according to example embodiment EX-1 wherein the insulating structure comprises aluminum oxide, titanium oxide, niobium oxide, tantalum oxide, zirconium oxide, or combinations of these.

EX-3. A device according to example embodiment EX-1 wherein the insulating structure comprises silicon oxide, silicon nitride, yttrium oxide, lanthanum oxide, hafnium oxide, or combinations of these.

EX-4. A device according to example embodiment EX-1 wherein the plurality of pores comprises pores which are continuous and substantially parallel to each other.

EX-5. A device according to example embodiment EX-1 wherein the plurality of pores comprises pores with diameters within the range of about 1 to about 200 nanometers.

EX-6. A device according to example embodiment EX-1 wherein the plurality of pores comprises pores with lengths within the range of 10 nanometers to 10 microns.

Ex-7. A device according to example embodiment EX-1 wherein the plurality of pores comprises pores with lengths of greater than 10 microns.

EX-8. A device according to example embodiment EX-1 wherein the structure has pore densities of about 10⁶ to about 10¹⁴ per square centimeter.

EX-9. A device according to example embodiment EX-1 wherein anodization of a metal is used to form the insulating structure that comprises the plurality of pores.

EX-10. A device according to example embodiment EX-9 wherein the metal comprises aluminum, titanium, niobium, tantalum, zirconium, or combinations of these.

EX-11. A device according to example embodiment EX-1 wherein at least a given percentage of pores is known to contain carbon nanotubes.

EX-12. A device according to example embodiment EX-1 wherein each pore contains zero, one, or multiple carbon nanotubes.

EX-13. A device according to example embodiment EX-1 wherein the at least one junction is a p-n junction.

EX-14. A device according to example embodiment EX-1 wherein the at least one junction connects a first p-type semiconducting segment to a second p-type semiconducting segment, where the segments have different carrier concentrations.

EX-15. A device according to example embodiment EX-14 wherein the junction connects a lightly doped p semiconducting segment to a more heavily doped p semiconducting segment.

EX-16. A device according to example embodiment EX-15 wherein the junction connects a moderately doped p semiconducting segment to a more heavily doped p semiconducting segment.

EX-17. A device according to example embodiment EX-1 wherein the at least one junction connects a first n-type semiconducting segment to a second n-type semiconducting segment, where the segments have different carrier concentrations.

EX-18. A device according to example embodiment EX-14 wherein the junction connects a lightly doped n semiconducting segment to a more heavily doped n semiconducting segment.

EX-19. A device according to example embodiment EX-14 wherein the junction connects a moderately doped n semiconducting segment to a more heavily doped n semiconducting segment.

EX-20. A device according to example embodiment EX-1 wherein the junction connects a semiconducting segment to metallic or semimetallic segment.

EX-21. A device according to example embodiment EX-1 wherein the junction connects two regions with different physical properties.

EX-22. A device according to example embodiment EX-21 wherein the two regions have different defect densities.

EX-23. A device according to example embodiment EX-21 wherein the two segments have different chiralities.

EX-24. A device according to example embodiment EX-21 wherein the two segments have different crystallinities, qualities, or purities.

EX-25. A device according to example embodiment EX-1 wherein at least one gate electrode is added to the device.

EX-26. A device according to example embodiment EX-26 wherein the at least one gate electrode is used to modulate at least part of the device.

EX-27. A device according to example embodiment EX-1 wherein the device operates at DC or frequencies up to 100 Hz.

EX-28. A device according to example embodiment EX-1 wherein the device operates at frequencies up to 1 MHz.

EX-29. A device according to example embodiment EX-1 wherein the device operates at frequencies up to and greater than 1 MHz.

EX-30. A device according to example embodiment EX-1 wherein the carbon nanotubes are synthesized within the at least some of the plurality of pores.

EX-31. A device according to example embodiment EX-30 wherein chemical vapor deposition was used to synthesize the carbon nanotubes.

EX-32. A device according to example embodiment EX-31 wherein effective catalyst was used to synthesize the carbon nanotubes.

EX-33. A device according to example embodiment EX-32 wherein the catalyst comprises Fe, Co, Ni, Mo, or combinations of these.

EX-34. A device according to example embodiment EX-30 wherein the at least one junction is formed during the synthesis of the carbon nanotubes.

EX-35. A device according to example embodiment EX-30 wherein the at least one junction is formed after the synthesis of the carbon nanotubes.

EX-36. A device according to example embodiment EX-30 wherein at least a given percentage of carbon nanotubes are known or estimated to have lengths greater than or about equal to the length of the pores.

EX-37. A device according to example embodiment EX-30 wherein unwanted carbon nanotubes, or portions of these, are destroyed, modified, or removed by chemical, mechanical, or electrical techniques.

EX-38. A device according to example embodiment EX-1 wherein the carbon nanotubes are transferred to the at least some of the plurality of pores.

EX-39. A device according to example embodiment EX-38 wherein the carbon nanotubes, prior to being transferred to the pores, were synthesized by chemical vapor deposition, arc-discharge, or laser ablation techniques.

EX-40. A device according to example embodiment EX-38 wherein the carbon nanotubes were in solutions or suspensions for use in transfer to the structure.

EX-41. A device according to example embodiment EX-40 wherein the solution or suspension flowed into or through the pores in the structure and carbon nanotubes were deposited within the pores.

EX-42. A device according to example embodiment EX-38 wherein at least a given percentage of carbon nanotubes have lengths greater than or about equal to the length of the pores.

EX-43. A device according to example embodiment EX-38 wherein unwanted carbon nanotubes, or portions of these, were destroyed, modified, or removed by chemical, mechanical, or electrical techniques.

EX-44. A device according to example embodiment EX-1 wherein the at least one junction is formed by modifying or doping at least some portion of the carbon nanotubes by electrical, chemical, or physical techniques.

EX-45. A device according to example embodiment EX-1 wherein the at least one junction is formed using one or more gates, e.g. electrostatic doping.

EX-46. A device according to example embodiment EX-1, wherein the at least one junction is formed by a split gate.

EX-47. A device according to example embodiment EX-46 wherein the split gate forms a p-n junction.

EX-48. A device according to example embodiment EX-1 wherein the at least one junction is formed by adsorbed species on at least some portion of the carbon nanotubes.

EX-49. A device according to example embodiment EX-1 wherein the at least one junction is formed by removing adsorbed species on a least some portion of the carbon nanotubes.

EX-50. A device according to example embodiment EX-49 wherein vacuum annealing, heating in reducing atmospheres, heating in inert atmospheres, heating in nitrogen, radiation, ultraviolet radiation, chemical methods, or combinations of these are used.

EX-51. A device according to example embodiment EX-1 wherein the at least one junction is formed by charge transfer from species in contact with or near at least some portion of the carbon nanotubes.

EX-52. A device according to example embodiment EX-51 wherein the species comprises a polymer, nanoparticles, gas molecules, organic molecules, metal atoms, liquid, or combinations of these.

EX-53. A device according to example embodiment EX-1 wherein the structure is made of a material and the structure's pore pattern was obtained by being transferred onto the structure via a pore-pattern template by chemical, electrochemical, dry etching, or mechanical techniques.

EX-54. A device according to example embodiment EX-53 wherein the material is silicon oxide, silicon nitride, plastic, polymer, glass, or quartz.

EX-55. A device according to example embodiment EX-53 wherein the pore-pattern template comprises aluminum oxide, titanium oxide, niobium oxide, tantalum oxide, zirconium oxide, or combinations of these.

EX-56. A device according to example embodiment EX-1 wherein the pores are at least partially filled after the carbon nanotubes are synthesized in the pores or transferred to the pores.

EX-57. A device according to example embodiment EX-56 wherein the filler is used to passivate or protect at least some portion of the carbon nanotubes.

EX-58. A device according to example embodiment EX-56 wherein the filler is used to dope or electrically modify at least some portion of the carbon nanotubes.

EX-59. A device according to example embodiment EX-1 wherein the device is capable of achieving high current densities of at least about 100 Ampere per square centimeter.

EX-60. A device according to example embodiment EX-1 wherein the device is capable of achieving high current densities of at least about 1000 Ampere per square centimeter.

EX-61. A diode, rectifier, silicon controlled rectifier, or thyristor comprising the device according to example embodiment EX-1.

EX-62. A power diode or power rectifier comprising the device according to example embodiment EX-1.

EX-63. A diode, rectifier, silicon controlled rectifier, or thyristor comprising:

a structure that defines a plurality of pores; carbon nanotubes within at least some of the plurality of pores;
at least one junction in multiple ones of the carbon nanotubes, where the junction defines two regions of different properties;
a first electrode on a first side of the structure connecting to multiple ones of the carbon nanotubes; and
a second electrode on a second (e.g. opposing) side of the structure connecting to multiple ones of the carbon nanotubes,
where the diameter of the carbon nanotubes does not significantly change on either side of a junction.

EX-64. A diode, rectifier, silicon controlled rectifier, or thyristor according to example embodiment EX-63 wherein the structure with pores comprises aluminum oxide, titanium oxide, niobium oxide, tantalum oxide, zirconium oxide, silicon oxide, silicon nitride, zinc oxide, or combinations of these.

EX-65. A diode, rectifier, silicon controlled rectifier, or thyristor according to example embodiment EX-63 wherein the structure with pores comprises aluminum oxide, titanium oxide, niobium oxide, tantalum oxide, zirconium oxide, silicon oxide, silicon nitride, yttrium oxide, lanthanum oxide, hafnium oxide, zinc oxide, silicon, gallium nitride, silicon carbide, gallium arsenide, plastic, polymer, glass, quartz, carbon, a metal, copper, a noble metal, or combinations of these.

EX-66. A diode, rectifier, silicon controlled rectifier, or thyristor according to example embodiment EX-63 wherein the structure with pores is semiconductive.

EX-67. A diode, rectifier, silicon controlled rectifier, or thyristor according to example embodiment EX-63 wherein the structure with pores is conductive.

EX-68. A diode, rectifier, silicon controlled rectifier, or thyristor according to example embodiment EX-63 wherein the structure is made of a material and the structure's pore pattern was obtained by being transferred onto the structure via a pore-pattern template by chemical, electrochemical, dry etching, or mechanical techniques.

EX-69. A diode, rectifier, silicon controlled rectifier, or thyristor according to example embodiment EX-68 wherein the material is titanium oxide, niobium oxide, tantalum oxide, zirconium oxide, silicon oxide, silicon nitride, zinc oxide, silicon, gallium nitride, silicon carbide, gallium arsenide, plastic, polymer, glass, quartz, carbon, or a metal, or combinations of these.

EX-70. A diode, rectifier, silicon controlled rectifier, or thyristor according to example embodiment EX-63 wherein the structure with pores comprises two or more layers.

EX-71. A diode, rectifier, silicon controlled rectifier, or thyristor according to example embodiment EX-70 wherein one of the layers comprises aluminum oxide, titanium oxide, niobium oxide, tantalum oxide, zirconium oxide, or combinations of these; and another one of the layers comprises a conductive material.

EX-72. A device according to example embodiment EX-1 wherein one or more of the electrodes is formed by connecting multiple smaller electrodes.

EX-73. A device according to example embodiment EX-72 wherein the smaller electrodes comprise a nanowire, nanoparticle, nanoribbon, or related nanostructure.

In an embodiment, the invention is a device including multiple junctions fabricated according to techniques of the invention and other techniques. For example, a nanotube of a device may include a first junction and two segments with different characteristics or properties. Furthermore, that nanotube may be further connected to a nanowire as described in U.S. patent application Ser. No. 11/162,548, which is incorporated by reference. This will form a second junction.

The first junction may be referred to as a homogeneous junction, since this junction is formed using the nanotube itself. The second junction may be referred to as a heterogeneous junction since this junction is formed using the nanotube and another material—the nanowire, in this case. In other cases, the heterogeneous junction may be formed using a material other than a nanowire. There may be any number of homogeneous junctions and any number of heterogeneous junctions. For example, there may be one, two, three, four, five, six, seven, eight, nine, ten, or eleven or more homogeneous junctions. Any number of homogeneous junctions may be combined with one, two, three, four, five, six, seven, eight, nine, ten, or eleven or more heterogeneous junctions.

This description of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications. This description will enable others skilled in the art to best utilize and practice the invention in various embodiments and with various modifications as are suited to a particular use. The scope of the invention is defined by the following claims.

1. A device comprising:
a structure having a first surface and a second surface, wherein the structure has at least one pore having a first end at the first surface and a second end at the second surface, and the pore extends from the first to the second surface; and
a carbon nanotube, extending from the first end of the pore to the second end, wherein the carbon nanotube has a first segment and a second segment, and the first segment has a different characteristic from the second segment.

2. The device of claim 1 wherein an outside diameter of the carbon nanotube is substantially the same.

3. The device of claim 1 wherein the carbon nanotube has at most two ends.

4. The device of claim 1 wherein the first segment has a p-type semiconductor characteristic and the second segment has an n-type semiconductor characteristic.

5. The device of claim 1 wherein the first segment of the carbon nanotube is more heavily doped than the second segment of the carbon nanotube.

6. The device of claim 1 wherein the first segment of the carbon nanotube has a p+ doping characteristic and the second segment of the carbon nanotube has a p− doping characteristic.

7. The device of claim 1 wherein the first segment of the carbon nanotube has a n+ doping characteristic and the second segment of the carbon nanotube has a n− doping characteristic.

8. The device of claim 1 wherein the first segment meets the second segment at a first junction, and the carbon nanotube has a third segment which meets the second segment at a second junction.

9. The device of claim 1 wherein the carbon nanotube is a single-walled carbon nanotube.

10. The device of claim 1 wherein the carbon nanotube is a multiwalled carbon nanotube.

11. The device of claim 1 further comprising a first electrode formed on the first surface and coupling to the first end of the carbon nanotube.

12. The device of claim 11 further comprising a second electrode formed on the second surface and coupling to the second end of the carbon nanotube.

13. The device of claim 1 wherein the structure comprises an insulator material.

14. The device of claim 1 wherein the first segment is equal in length to the second segment.

15. The device of claim 1 wherein the first segment is a different length from the second segment.

16. A device comprising:
a structure having a first surface and a second surface, wherein the structure has a plurality of pores, each having a first end at the first surface and a second end at the second surface, and each pore extending from the first to the second surface; and
a plurality of carbon nanotubes, each extending from the first end of the pores to the second end of the pores, wherein each carbon nanotube has n junctions and n+1 segments, where n is an integer, and at least two segment of each carbon nanotube has different characteristics.

17. The device of claim 16 wherein the pores are arranged in a hexagonal pattern.

18. The device of claim 16 wherein a first segment of a carbon nanotube is n doped and a second segment of the carbon nanotube is p doped.

19. The device of claim 16 wherein a first segment of a carbon nanotube is more heavily doped than a second segment of the carbon nanotube.

20. The device of claim 16 wherein a carbon nanotube is a single-walled carbon nanotube.

21. The device of claim 16 wherein a carbon nanotube is a multiwalled carbon nanotube.

22. A device comprising:
a structure having a first surface and a second surface, wherein the structure has a plurality of pores, each having a first end at the first surface and a second end at the second surface, and each pore extending from the first to the second surface; and
a plurality of carbon nanotubes, each extending from the first end of the pores to the second end of the pores, wherein each carbon nanotube has a characteristic which varies along a length of the carbon nanotube.

23. The device of claim 1 further comprising a gate electrode extending from the first surface into the structure.

24. The device of claim 23 wherein the gate electrode comprises polysilicon.

25. The device of claim 16 further comprising a gate electrode extending from the first surface into the structure.

26. The device of claim 25 wherein the gate electrode comprises polysilicon.

27. The device of claim 26 further comprising a gate electrode extending from the first surface into the structure.

28. A battery recharging circuit comprising at least one device as recited in claim 1.

29. An automotive system comprising at least one device as recited in claim 1.

30. A computer system comprising at least one device as recited in claim 1.

31. A portable electronic device comprising at least one device as recited in claim 1.

32. A method of making a device comprising:
anodizing an aluminum substrate to produce an alumina template with a plurality of pores, each having a pore diameter;
exposing the alumina template having pores to a hydrocarbon gas at a temperature to grow carbon nanotubes in the pores, each carbon nanotube having an outer diameter less than the pore diameter in the template in which said carbon nanotube is produced;
doping a first segment of each carbon nanotube differently from a second segment of each carbon nanotube;
forming a first electrode region to electrically couple to first ends of the carbon nanotubes; and
forming a second electrode region to electrically couple to second ends of the carbon nanotubes.

33. The method of claim 32 further comprising:
forming a gate region on the alumina template.

34. The process of claim 32 further comprising:
depositing a catalyst into the pores before exposing the alumina template containing pores to a hydrocarbon gas.

35. The process of claim 32 wherein the aluminum substrate is anodized under conditions to produce the plurality of pores substantially parallel to each other.

36. The process of claim 34 wherein the catalyst is at least one of cobalt or an alloy of cobalt.

37. The process of claim 34 wherein the catalyst is at least one of iron or an alloy of iron.

38. The process of claim 34 wherein the catalyst is at least one of nickel or an alloy of nickel.

39. The process of claim 33 wherein the gate region extends into the alumina template.

40. The process of claim 32 wherein the exposing the alumina template containing pores to a hydrocarbon gas occurs at a temperature in a range from about 600 degrees Celsius to about 650 degrees Celsius.

41. The process of claim 32 further comprising:
before exposing the alumina template containing pores to a hydrocarbon gas, depositing a catalyst into a bottom of the pores.

42. The process of claim 32 wherein the carbon nanotubes are multiwalled carbon nanotubes.

43. The process of claim 32 wherein the carbon nanotubes are single-walled carbon nanotubes.
transistors do not have bulk node connections.

44. A method comprising:
providing a porous structure;
processing to obtain a plurality of nanotubes in pores of the porous structure; and
processing first segments of the nanotubes to have a first characteristic different from a second characteristic of second segments of the nanotubes.

45. The method of claim 44 further comprising:
processing the second segments of the nanotubes to have the second characteristic.

46. The method of claim 44 wherein the processing first segments of the nanotubes to have a first characteristic different from a second characteristic of second segments of the nanotubes comprises:
filling pores of the porous structure with a first material to surround the first segments and not the second segments of the nanotubes.

47. The method of claim 46 wherein the processing first segments of the nanotubes to have a first characteristic different from a second characteristic of second segments of the nanotubes comprises:
filling pores of the porous structure with a second material to surround the second segments and not the first segments of the nanotubes.

48. The method of claim 46 wherein the processing first segments of the nanotubes to have a first characteristic different from a second characteristic of second segments of the nanotubes comprises:
filling pores of the porous structure with a gas to surround the second segments and not the first segments of the nanotubes.

49. The method of claim 46 wherein the first material is a polymer.

50. The method of claim 44 wherein the processing first segments of the nanotubes to have a first characteristic different from a second characteristic of second segments of the nanotubes comprises:
filling pores of the porous structure with a polymer material to surround the first and second segments.

51. The method of claim 44 further comprising:
providing a first electrode to couple to first ends of the carbon nanotubes;
providing a second electrode to couple to second ends of the carbon nanotubes;
forming a gate electrode on the porous structure; and
applying voltages to the gate and the first and second electrode to cause a current to flow through the carbon nanotubes, wherein a plurality of nonsemiconducting carbon nanotubes are destroyed by the current.

52. A device comprising:
an insulator structure that defines a plurality of pores;
a plurality of carbon nanotubes within at least some of the plurality of pores;
at least one junction in multiple ones of the carbon nanotubes, where the junction defines a first region and a second region having of different properties;
a first electrode on a first side of the structure connecting to multiple ones of the carbon nanotubes; and
a second electrode on a second side of the structure connecting to multiple ones of the carbon nanotubes, wherein a diameter of a first region of a carbon nanotube is about equal to a diameter of a second region of the carbon nanotube.

53. The device of claim 52 wherein the insulator structure comprises at least one of aluminum oxide, titanium oxide, niobium oxide, tantalum oxide, zirconium oxide, silicon oxide, silicon nitride, yttrium oxide, lanthanum oxide, or hafnium oxide.

54. The device of claim 52 wherein the junction is a p-n junction.

55. The device of claim 52 wherein the junction couples a lightly doped p semiconducting region to a more heavily doped p semiconducting region.

56. The device of claim 52 wherein the at least one junction couples a first dopant semiconducting region to a second dopant semiconducting region, where the regions have different carrier concentrations.

57. The device of claim 56 wherein the first dopant and second dopant are p dopants.

58. The device of claim 56 wherein the first dopant and second dopant are n dopants.

59. The device of claim 52 wherein the junction connects a semiconducting segment to metallic segment.

60. The device of claim 52 wherein the junction connects a semiconducting segment to semimetallic segment.

61. The device of claim 52 wherein the first and second regions have different defect densities.

62. The device of claim 52 wherein the first and second regions have different chiralities.

63. The device of claim 52 wherein junction is formed during synthesis of the carbon nanotubes.

64. The device of claim 52 wherein junction is formed after synthesis of the carbon nanotubes.
